(19) United States
(12) Patent Application Publication
(10) Pub. No.: US 2024/0337936 A1
(43) Pub. Date: Oct. 10, 2024

(54) POSITIVE RESIST COMPOSITION

(71) Applicant: ZEON CORPORATION, Chiyoda-ku, Tokyo (JP)

(72) Inventor: Sinfu YEH, Chiyoda-ku, Tokyo (JP)

(73) Assignee: ZEON CORPORATION, Chiyoda-ku, Tokyo (JP)

(21) Appl. No.: 18/292,027

(22) PCT Filed: Aug. 8, 2022
(86) PCT No.: PCT/JP2022/030334

§ 371 Date: Jan. 25, 2024

(30) Foreign Application Priority Data
Aug. 25, 2021 (JP) 2021-137533

(51) Int. Cl. G03F 7/039

(52) U.S. Cl. CPC G03F 7/039

(57) ABSTRACT

Provided is a positive resist composition that is capable of forming a resist pattern having little resist pattern top loss. The positive resist composition contains a copolymer A, a copolymer B, and a solvent. A difference between surface free energy of the copolymer A and surface free energy of the copolymer B is 4 mJ/m² or more. A proportion constituted by mass (B) of the copolymer B relative to total mass (A+B) of the copolymer A and the copolymer B in the positive resist composition and thickness (T nm) of a positive resist film formed by applying the positive resist composition onto a substrate satisfy a relationship expressed by formula (1): B/(A+B)×100(%)≥5.6/T×100(%).

### TECHNICAL FIELD

The present disclosure relates to a positive resist composition.

### BACKGROUND

Polymers that display increased solubility in a developer after undergoing main chain scission through irradiation with ionizing radiation, such as an electron beam, or short-wavelength light, such as ultraviolet light, are conventionally used as main chain scission-type positive resists in fields such as semiconductor production. (Hereinafter, the term “ionizing radiation or the like” is used to refer collectively to ionizing radiation and short-wavelength light.)

For example, PTL (Patent Literature) 1 discloses a positive resist composition containing, as a main chain scission-type positive resist having excellent sensitivity to ionizing radiation or the like and heat resistance, a positive resist that is formed of a copolymer including a 1-phenyl-1-trifluoromethyl-2,2,2-trifluoroethyl α-chloroacrylate unit and an α-methylstyrene unit.

### CITATION LIST

### Patent Literature

PTL 1: JP2018-154754A

### SUMMARY

### Technical Problem

However, there is room for further improvement of a resist pattern formed using the conventional positive resist composition described above in terms of reducing loss of the top of the resist pattern (top loss).

Accordingly, an object of the present disclosure is to provide a positive resist composition that is capable of forming a resist pattern having little resist pattern top loss.

### Solution to Problem

The inventor conducted diligent studies with the aim of achieving the object set forth above. The inventor made a new discovery that in the case of a positive resist composition that contains specific copolymers A and B and for which a specific relationship is satisfied by the mass proportion of the copolymer B relative to total mass of the copolymer A and the copolymer B in the positive resist composition and the thickness of a positive resist film formed by applying the positive resist composition onto a substrate, this positive resist composition is capable of forming a resist pattern having little resist pattern top loss. In this manner, the inventor completed the present disclosure.

Specifically, the present disclosure aims to advantageously solve the problem set forth above, and, according to the present disclosure, positive resist compositions according to the following [1] to [5] are provided.

[1] A positive resist composition comprising: a copolymer A that is of a main chain scission-type and that includes a fluorine substituent; a copolymer B that is of a main chain scission-type and that includes a fluorine substituent; and a solvent, wherein a difference between surface free energy of the copolymer A and surface free energy of the copolymer B is 4 mJ/m² or more, and a mass proportion of the copolymer B relative to total mass of the copolymer A and the copolymer B in the positive resist composition and thickness of a positive resist film formed by applying the positive resist composition onto a substrate satisfy a relationship expressed by formula (1), shown below

$$B / ( A + B ) \times 100 ( \% ) \geq 5.6 / T \times 100 ( \% ) \qquad ( 1 )$$

where, in formula (1), A represents mass of the copolymer A in the positive resist composition, B represents mass of the copolymer B in the positive resist composition, and T represents thickness, in units of nanometers, of the positive resist film.

By using a positive resist composition that contains specific copolymers A and B and for which a relationship expressed by the preceding formula (1) is satisfied by the mass proportion of the copolymer B relative to total mass of the copolymer A and the copolymer B and the thickness of a positive resist film formed by applying the positive resist composition onto a substrate in this manner, it is possible to form a resist pattern having little resist pattern top loss.

Note that when a copolymer is referred to as a “main chain scission-type”in the present disclosure, this means that the copolymer has a property of undergoing scission of a main chain thereof in a situation in which the copolymer is irradiated with ionizing radiation or the like, such as an electron beam or extreme ultraviolet light (EUV).

Moreover, the “positive resist film” that is referred to in the present disclosure (hereinafter, also referred to simply as a “resist film”) is, more specifically, a film that is obtained by applying the positive resist composition onto a substrate and heating the positive resist composition that has been applied at a temperature that is at least 10° C. higher than a boiling point of the solvent contained in the positive resist composition for at least 30 seconds.

Furthermore, the “surface free energy of the copolymer A” and the “surface free energy of the copolymer B” that are referred to in the present disclosure can be determined according to methods described in the EXAMPLES section of the present specification.

[2] The positive resist composition according to the foregoing [1], not substantially comprising a component having a weight-average molecular weight (Mw) of less than 1,000.

By using a positive resist composition that does not substantially contain a component having a weight-average molecular weight (Mw) of less than 1,000 in this manner, it is possible to further reduce resist pattern top loss.

Note that the “weight-average molecular weight” referred to in the present disclosure can be measured as a standard polystyrene-equivalent value by gel permeation chromatography.

Also note that the phrase “not substantially comprising” as used in the present disclosure means not actively compounded, exclusive of a case in which mixing in thereof is unavoidable. More specifically, this indicates that the proportional content of a component having a weight-average molecular weight (Mw) of less than 1,000 in the positive resist composition is less than 0.05 mass %.

[3] The positive resist composition according to the foregoing [1] or [2], further satisfying a relationship expressed by formula (2), shown below,

$$18. / T \times 100 ( \% ) \geq B / ( A + B ) \times 100 ( \% ) \qquad ( 2 )$$

where, in formula (2), A represents mass of the copolymer A in the positive resist composition, B represents mass of the copolymer B in the positive resist composition, and T represents thickness, in units of nanometers, of the positive resist film.

When the positive resist composition satisfies the relationship expressed by the preceding formula (2) in this manner, the presence of residues in a resist pattern can be effectively suppressed.

[4] The positive resist composition according to any one of the foregoing [1] to [3], wherein the copolymer A includes:
a monomer unit (I) represented by formula (I), shown below,

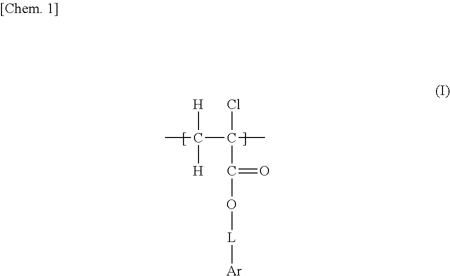

where, in formula (I), L is a divalent linking group that includes a fluorine atom, and Ar is an optionally substituted aromatic ring group; and
a monomer unit (II) represented by formula (II), shown below,

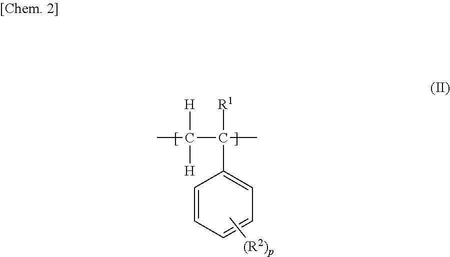

where, in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different.

By using a copolymer A that includes the monomer unit (I) and the monomer unit (II) in this manner, it is possible to form a resist pattern having further reduced resist pattern top loss and high contrast.

Note that the term “optionally substituted” as used in the present disclosure means “unsubstituted or having one or more substituents”.

[5] The positive resist composition according to any one of the foregoing [1] to [4], wherein the copolymer B includes:
a monomer unit (III) represented by formula (III), shown below,

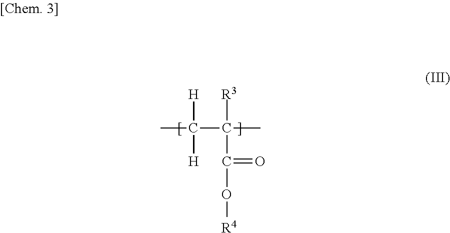

where, in formula (III), R³ is a hydrogen atom, an alkyl group, a halogen atom, a haloalkyl group, a cyano group, an alkoxy group, an acyl group, or an alkyl ester group, and R⁴ is an organic group including 5 or 7 fluorine atoms; and
a monomer unit (II) represented by formula (II), shown below,

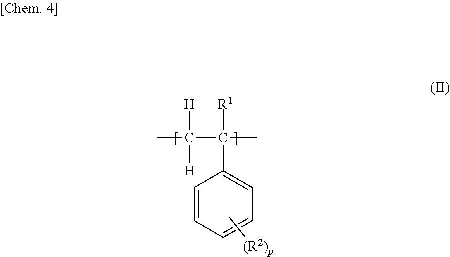

where, in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different.

By using a copolymer B that includes the monomer unit (III) and the monomer unit (II) in this manner, it is possible to form a resist pattern having further reduced resist pattern top loss and even higher contrast.

### Advantageous Effect

According to the present disclosure, it is possible to provide a positive resist composition that is capable of forming a resist pattern having little resist pattern top loss.

### BRIEF DESCRIPTION OF THE DRAWINGS

In the accompanying drawings:

FIG. 1 illustrates a relationship between a mass proportion of a copolymer B relative to total mass of copolymers A and B in a positive resist composition and thickness of a positive resist film formed by applying the positive resist composition onto a substrate in Examples 1 to 55 and Comparative Examples 1 to 15;

FIG. 2 illustrates a relationship between a mass proportion of a copolymer B relative to total mass of copolymers A and B in a positive resist composition and thickness of a positive resist film formed by applying the positive resist composition onto a substrate in Examples 56 to 110 and Comparative Examples 16 to 30;

FIG. 3 illustrates a relationship between a mass proportion of a copolymer B relative to total mass of copolymers A and B in a positive resist composition and thickness of a positive resist film formed by applying the positive resist composition onto a substrate in Examples 111 to 120 and Comparative Examples 31 and 32; and

FIG. 4 illustrates a relationship between a mass proportion of a copolymer B relative to total mass of copolymers A and B in a positive resist composition and thickness of a positive resist film formed by applying the positive resist composition onto a substrate in Examples 121 to 130 and Comparative Examples 33 and 34.

### DETAILED DESCRIPTION

The following provides a detailed description of embodiments of the present disclosure.

A presently disclosed positive resist composition is used to form a resist film in the formation of a resist pattern using ionizing radiation or the like, such as an electron beam or EUV.

### (Positive Resist Composition)

The presently disclosed positive resist composition contains specific copolymers A and B and a solvent, and optionally further contains known additives that can be compounded in positive resist compositions.

Features of the presently disclosed positive resist composition are that a difference between the surface free energy of the copolymer A and the surface free energy of the copolymer B is 4 mJ/m² or more and that a mass proportion of the copolymer B relative to total mass of the copolymer A and the copolymer B in the positive resist composition and the thickness of a positive resist film formed by applying the positive resist composition onto a substrate satisfy a relationship expressed by the following formula (1). As a result thereof, it is possible to form a resist pattern having little resist pattern top loss by using the presently disclosed positive resist composition.

$$B / ( A + B ) \times 100 ( \% ) \geq 5.6 / T \times 100 ( \% ) \qquad ( 1 )$$

In formula (1), A represents mass of the copolymer A in the positive resist composition, B represents mass of the copolymer B in the positive resist composition, and T represents thickness (nm) of the positive resist film.

Note that no specific limitations are placed on the aforementioned substrate. For example, a substrate that is used in a subsequently described method of forming a resist pattern using the presently disclosed positive resist composition may be adopted.

The presently disclosed positive resist composition preferably does not substantially contain a component having a weight-average molecular weight (Mw) of less than 1,000. More specifically, the proportional content of a component having a weight-average molecular weight (Mw) of less than 1,000 in the positive resist composition is preferably less than 0.05 mass %, more preferably less than 0.01 mass %, and even more preferably less than 0.001 mass %. By using a positive resist composition that does not substantially contain a component having a weight-average molecular weight (Mw) of less than 1,000, it is possible to further reduce resist pattern top loss.

The presently disclosed positive resist composition preferably further satisfies a relationship expressed by the following formula (2). When the relationship expressed by formula (2) is satisfied, the presence of residues in a resist pattern can be effectively suppressed.

$$18. / T \times 100 ( \% ) \geq B / ( A + B ) \times 100 ( \% ) \qquad ( 2 )$$

Note that A, B, and T in formula (2) are the same as in formula (1).

### <Copolymer A>

The copolymer A that is contained in the presently disclosed positive resist composition is a main chain scission-type copolymer that includes a fluorine substituent. The fluorine substituent is not specifically limited so long as it is a substituent that includes a fluorine atom.

### {Surface Free Energy of Copolymer A}

The surface free energy of the copolymer A is preferably 28 mJ/m² or more, more preferably 29 mJ/m² or more, and even more preferably 30 mJ/m² or more, and is preferably 35 mJ/m² or less, more preferably 34 mJ/m² or less, and even more preferably 33 mJ/m² or less.

From a viewpoint of increasing the contrast of a resist pattern, the copolymer A that is contained in the presently disclosed positive resist composition preferably includes:
a monomer unit (I) represented by formula (I), shown below,

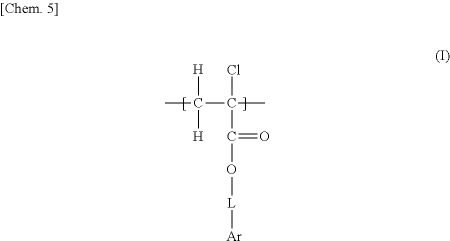

(in formula (I), L is a divalent linking group that includes a fluorine atom, and Ar is an optionally substituted aromatic ring group); and
a monomer unit (II) represented by formula (II), shown below,

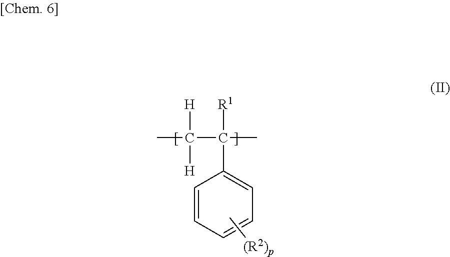

(in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different).

Note that although the copolymer A may also include any monomer units other than the monomer unit (I) and the monomer unit (II), the proportion constituted by the monomer unit (I) and the monomer unit (II) among all monomer units of the copolymer A is, in total, preferably 90 mol % or more, and more preferably 100 mol % (i.e., the copolymer A more preferably only includes the monomer unit (I) and the monomer unit (II)).

The monomer unit (I) is a structural unit that is derived from a monomer (a) represented by the following formula (a).

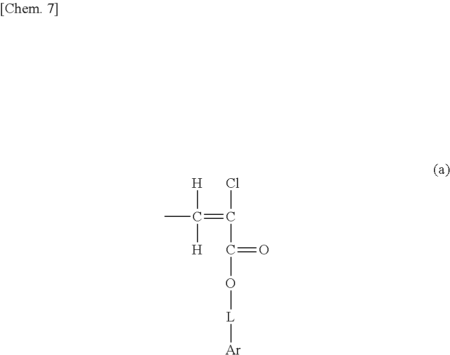

(In formula (a), L and Ar are the same as in formula (I).)

The divalent linking group including a fluorine atom that can constitute L in formula (I) and formula (a) may be a divalent chain alkyl group having a carbon number of 1 to 5 that includes a fluorine atom or the like, for example.

Moreover, Ar in formula (I) and formula (a) may be an optionally substituted aromatic hydrocarbon ring group or an optionally substituted aromatic heterocyclic group.

The aromatic hydrocarbon ring group may be a benzene ring group, a biphenyl ring group, a naphthalene ring group, an azulene ring group, an anthracene ring group, a phenanthrene ring group, a pyrene ring group, a chrysene ring group, a naphthacene ring group, a triphenylene ring group, an o-terphenyl ring group, an m-terphenyl ring group, a p-terphenyl ring group, an acenaphthene ring group, a coronene ring group, a fluorene ring group, a fluoranthene ring group, a pentacene ring group, a perylene ring group, a pentaphene ring group, a picene ring group, a pyranthrene ring group, or the like, for example, without any specific limitations.

The aromatic heterocyclic group may be a furan ring group, a thiophene ring group, a pyridine ring group, a pyridazine ring group, a pyrimidine ring group, a pyrazine ring group, a triazine ring group, an oxadiazole ring group, a triazole ring group, an imidazole ring group, a pyrazole ring group, a thiazole ring group, an indole ring group, a benzimidazole ring group, a benzothiazole ring group, a benzoxazole ring group, a quinoxaline ring group, a quinazoline ring group, a phthalazine ring group, a benzofuran ring group, a dibenzofuran ring group, a benzothiophene ring group, a dibenzothiophene ring group, a carbazole ring group, or the like, for example, without any specific limitations.

Examples of possible substituents of Ar include an alkyl group, a fluorine atom, and a fluoroalkyl group without any specific limitations. Examples of alkyl groups that are possible substituents of Ar include chain alkyl groups having a carbon number of 1 to 6 such as a methyl group, an ethyl group, a propyl group, an n-butyl group, and an isobutyl group. Examples of fluoroalkyl groups that are possible substituents of Ar include fluoroalkyl groups having a carbon number of 1 to 5 such as a trifluoromethyl group, a trifluoroethyl group, and a pentafluoropropyl group.

Of these examples, an optionally substituted aromatic hydrocarbon ring group is preferable as Ar in formula (I) and formula (a) from a viewpoint of sufficiently improving sensitivity to an electron beam or the like, with an unsubstituted aromatic hydrocarbon ring group being more preferable, and a benzene ring group (phenyl group) being even more preferable.

From a viewpoint of sufficiently improving sensitivity to an electron beam or the like, 1-phenyl-1-trifluoromethyl-2,2,2-trifluoroethyl α-chloroacrylate (ACAFPh) and 1-(4-methoxyphenyl)-1-trifluoromethyl-2,2,2-trifluoroethyl α-chloroacrylate (ACAFPhOMe) are preferable as the monomer (a) represented by formula (a) described above that can form the monomer unit (I) represented by formula (I) described above, and 1-phenyl-1-trifluoromethyl-2,2,2-trifluoroethyl α-chloroacrylate is more preferable. In other words, the copolymer A preferably includes either or both of a 1-phenyl-1-trifluoromethyl-2,2,2-trifluoroethyl α-chloroacrylate unit and a 1-(4-methoxyphenyl)-1-trifluoromethyl-2,2,2-trifluoroethyl α-chloroacrylate unit, and more preferably includes a 1-phenyl-1-trifluoromethyl-2,2,2-trifluoroethyl α-chloroacrylate unit.

Note that the proportion constituted by the monomer unit (I) among all monomer units of the copolymer A is not specifically limited and can be set as not less than 30 mol % and not more than 70 mol %, for example.

The monomer unit (II) is a structural unit that is derived from a monomer (b) represented by the following formula (b).

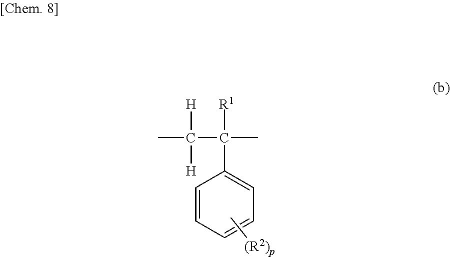

(In formula (b), R¹, R², and p are the same as in formula (II).)

The alkyl group that can constitute R¹ and R² in formula (II) and formula (b) may be an unsubstituted alkyl group having a carbon number of 1 to 5, for example, without any specific limitations. In particular, a methyl group or an ethyl group is preferable as the alkyl group that can constitute R¹ and R².

The halogen atom that can constitute R² in formula (II) and formula (b) may be a fluorine atom, a chlorine atom, a bromine atom, an iodine atom, or the like, without any specific limitations. In particular, a fluorine atom or an iodine atom is preferable as the halogen atom, and a fluorine atom is more preferable as the halogen atom.

The haloalkyl group that can constitute R² in formula (II) and formula (b) may be a fluoroalkyl group having a carbon number of 1 to 5, for example, without any specific limitations. In particular, a perfluoroalkyl group having a carbon number of 1 to 5 is preferable as the haloalkyl group, and a trifluoromethyl group is more preferable as the haloalkyl group.

From a viewpoint of improving ease of production of the copolymer A and main chain scission properties of the copolymer A upon irradiation with ionizing radiation or the like, R¹ in formula (II) and formula (b) is preferably an alkyl group having a carbon number of 1 to 5, and more preferably a methyl group.

Moreover, from a viewpoint of improving ease of production of the copolymer A and main chain scission properties of the copolymer A upon irradiation with ionizing radiation or the like, p in formula (II) and formula (b) is preferably 0 or 1.

The monomer (b) represented by formula (b) described above that can form the monomer unit (II) represented by formula (II) described above may be α-methylstyrene or a derivative thereof, such as the following (b-1) to (b-12), for example, without any specific limitations.

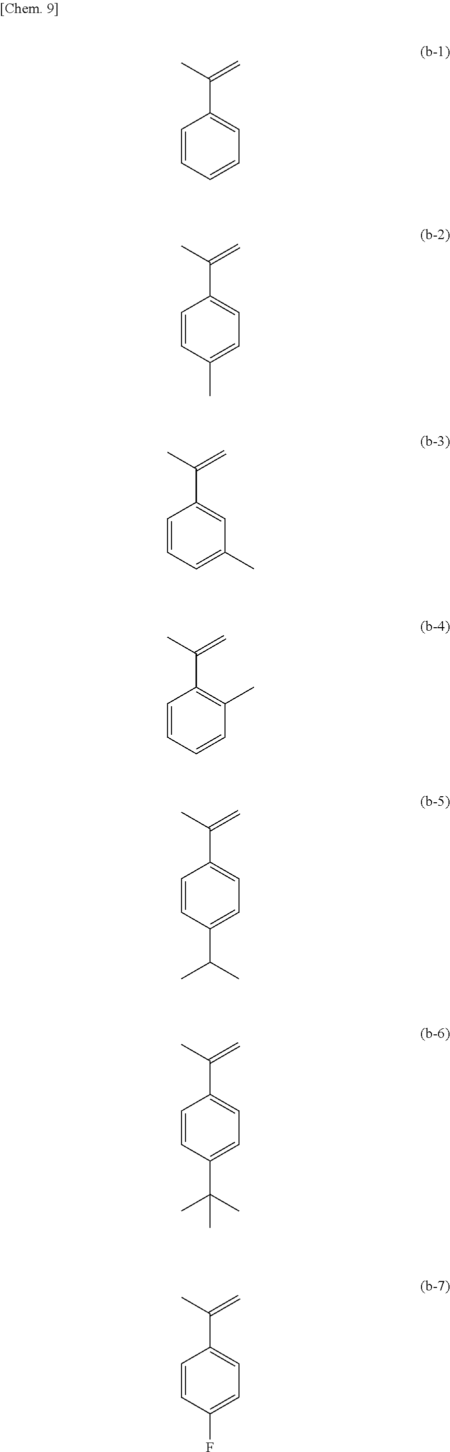

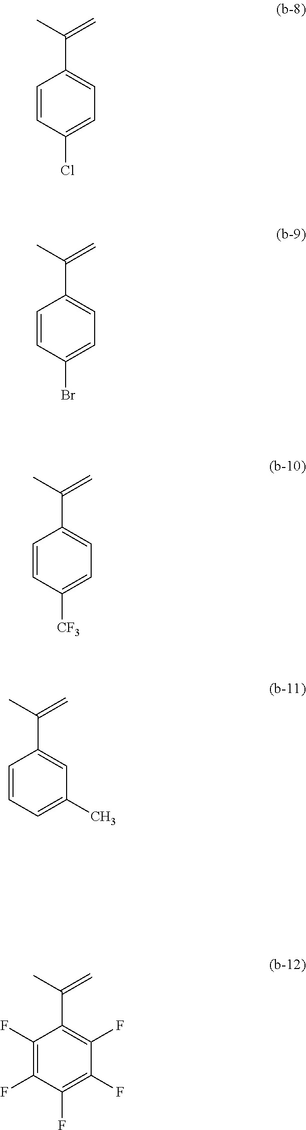

From a viewpoint of improving ease of production of the copolymer A and main chain scission properties of the copolymer A upon irradiation with an electron beam or the like, α-methylstyrene is preferable as the monomer (b) represented by formula (b) described above that can form the monomer unit (II). In other words, the copolymer A preferably includes an α-methylstyrene unit.

Note that the proportion constituted by the monomer unit (II) among all monomer units of the copolymer A is not specifically limited and can be set as not less than 30 mol % and not more than 70 mol %, for example.

### <Properties of Copolymer A>

### [Weight-Average Molecular Weight (Mw)]

The weight-average molecular weight (Mw) of the copolymer A is preferably 100,000 or more, more preferably 125,000 or more, and even more preferably 150,000 or more, and is preferably 600,000 or less, and more preferably 500,000 or less. When the weight-average molecular weight (Mw) of the copolymer A is not less than any of the lower limits set forth above, resist pattern top loss can be further reduced, and a resist pattern having further improved contrast can be formed. Moreover, when the weight-average molecular weight (Mw) of the copolymer A is not more than any of the upper limits set forth above, production of the positive resist composition can be facilitated.

### [Number-Average Molecular Weight (Mn)]

The number-average molecular weight (Mn) of the copolymer A is preferably 100,000 or more, and more preferably 110,000 or more, and is preferably 300,000 or less, and more preferably 200,000 or less. When the number-average molecular weight of the copolymer A is not less than any of the lower limits set forth above, resist pattern top loss can be even further reduced, and a resist pattern having even further improved contrast can be formed. Moreover, when the number-average molecular weight of the copolymer A is not more than any of the upper limits set forth above, the positive resist composition is even easier to produce.

### [Molecular Weight Distribution (Mw/Mn)]

The molecular weight distribution (Mw/Mn) of the copolymer A is preferably 1.20 or more, more preferably 1.25 or more, and even more preferably 1.30 or more, and is preferably 2.00 or less, more preferably 1.80 or less, and even more preferably 1.60 or less.

Note that the “number-average molecular weight” referred to in the present disclosure can be measured as a standard polystyrene-equivalent value by gel permeation chromatography, and that the “molecular weight distribution” referred to in the present disclosure can be determined by calculating a ratio of the weight-average molecular weight relative to the number-average molecular weight (weight-average molecular weight/number-average molecular weight).

### [Production Method of Copolymer A]

A copolymer A that includes the monomer unit (I) and the monomer unit (II) described above can be produced by, for example, polymerizing a monomer composition that contains the monomer (a) and the monomer (b), and then collecting and optionally purifying the resultant copolymer.

The chemical composition, molecular weight distribution, number-average molecular weight, and weight-average molecular weight of the copolymer A can be adjusted by altering the polymerization conditions and the purification conditions. In one specific example, the number-average molecular weight and the weight-average molecular weight can be increased by lowering the polymerization temperature. Moreover, the number-average molecular weight and the weight-average molecular weight can be increased by shortening the polymerization time. Furthermore, the molecular weight distribution can be reduced by performing purification.

### <Polymerization of Monomer Composition>

The monomer composition used in production of the copolymer A may be a mixture containing a monomer component that includes the monomer (a) and the monomer (b), an optionally used solvent, an optionally used polymerization initiator, and optionally added additives. Polymerization of the monomer composition may be carried out by a known method. In particular, it is preferable that cyclopentanone, water, or the like is used as the solvent.

A polymerized product obtained through polymerization of the monomer composition may, without any specific limitations, be collected by adding a good solvent such as tetrahydrofuran to a solution containing the polymerized product and subsequently dripping the solution to which the good solvent has been added into a poor solvent such as methanol, ethanol, 1-propanol, 1-butanol, 1-pentanol, or hexane to cause coagulation of the polymerized product.

### <Purification of Polymerized Product>

The method of purification in a case in which the obtained polymerized product is purified may be a known purification method such as reprecipitation or column chromatography without any specific limitations. Of these purification methods, purification by reprecipitation is preferable. Note that purification of the polymerized product may be performed repeatedly.

Purification of the polymerized product by reprecipitation is, for example, preferably carried out by dissolving the obtained polymerized product in a good solvent, such as tetrahydrofuran, and subsequently dripping the resultant solution into a mixed solvent of a good solvent, such as tetrahydrofuran, and a poor solvent, such as methanol, ethanol, 1-propanol, 1-butanol, 1-pentanol, or hexane, to cause precipitation of a portion of the polymerized product. When purification is carried out by dripping a solution of the polymerized product into a mixed solvent of a good solvent and a poor solvent in this manner, the molecular weight distribution, number-average molecular weight, and weight-average molecular weight of the resultant copolymer can easily be adjusted by altering the types and/or mixing ratio of the good solvent and the poor solvent. In one specific example, the molecular weight of copolymer that precipitates in the mixed solvent can be increased by increasing the proportion of the good solvent in the mixed solvent.

Also note that in a situation in which the polymerized product is purified by reprecipitation, polymerized product that precipitates in the mixed solvent of the good solvent and the poor solvent may be used as the copolymer A, or polymerized product that does not precipitate in the mixed solvent (i.e., polymerized product dissolved in the mixed solvent) may be used as the copolymer A, so long as the polymerized product that is used satisfies the desired properties. Polymerized product that does not precipitate in the mixed solvent can be collected from the mixed solvent by a known technique such as concentration to dryness.

### <Copolymer B>

The copolymer B that is contained in the presently disclosed positive resist composition is a main chain scission-type copolymer that includes a fluorine substituent. The fluorine substituent is not specifically limited so long as it is a substituent that includes a fluorine atom.

### {Surface Free Energy of Copolymer B}

The surface free energy of the copolymer B is preferably 18 mJ/m² or more, more preferably 19 mJ/m² or more, and even more preferably 20 mJ/m² or more, and is preferably 27 mJ/m² or less, more preferably 26 mJ/m² or less, and even more preferably 25 mJ/m² or less.

The difference between the surface free energy of the copolymer A and the surface free energy of the copolymer B (i.e., [surface free energy of copolymer A]−[surface free energy of copolymer B]) is 4 mJ/m² or more, preferably 5.5 mJ/m² or more, more preferably 6 mJ/m² or more, and even more preferably 6.5 mJ/m² or more, and is preferably 12 mJ/m² or less, more preferably 11 mJ/m² or less, and even more preferably 10 mJ/m² or less.

From a viewpoint of even further increasing the contrast of a resist pattern, it is preferable that the copolymer B includes:
a monomer unit (III) represented by formula (III), shown below,

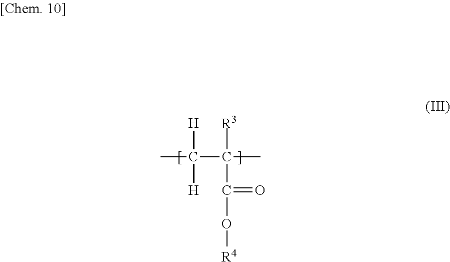

(in formula (III), R³ is a hydrogen atom, an alkyl group, a halogen atom, a haloalkyl group, a cyano group, an alkoxy group, an acyl group, or an alkyl ester group, and R⁴ is an organic group including 5 or 7 fluorine atoms); and
a monomer unit (II) represented by formula (II), shown below,

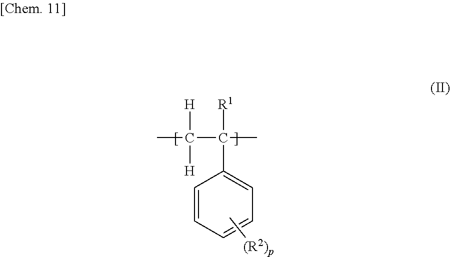

(in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different).

Note that although the copolymer B may also include any monomer units other than the monomer unit (III) and the monomer unit (II), the proportion constituted by the monomer unit (III) and the monomer unit (II) among all monomer units of the copolymer B is, in total, preferably 90 mol % or more, and more preferably 100 mol % (i.e., the copolymer B more preferably only includes the monomer unit (III) and the monomer unit (II)).

The monomer unit (III) is a structural unit that is derived from a monomer (c) represented by the following formula (c).

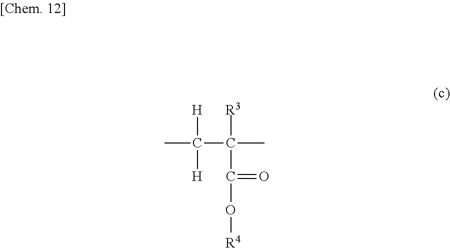

(In formula (c), R³ and R⁴ are the same as in formula (III).)

The alkyl group that can constitute R³ in formula (III) and formula (c) may be an unsubstituted alkyl group having a carbon number of 1 to 5 or the like, for example, without any specific limitations. In particular, a methyl group or an ethyl group is preferable as the alkyl group that can constitute R³.

The halogen atom that can constitute R³ in formula (III) and formula (c) may be a fluorine atom, a chlorine atom, a bromine atom, an iodine atom, or the like, without any specific limitations. In particular, a fluorine atom and a chlorine atom are preferable as the halogen atom that can constitute R³.

The haloalkyl group that can constitute R³ in formula (III) and formula (c) may be a fluoroalkyl group having a carbon number of 1 to 6 without any specific limitations. In particular, a perfluoroalkyl group having a carbon number of 1 to 6 is preferable as the haloalkyl group that can constitute R³.

The alkoxy group that can constitute R³ in formula (III) and formula (c) may be an alkoxy group having a carbon number of 1 to 5 or the like, for example, without any specific limitations. In particular, a methoxy group, an ethoxy group, or a propoxy group is preferable as the alkoxy group that can constitute R³.

The acyl group that can constitute R³ in formula (III) and formula (c) may be an acyl group having a carbon number of 1 to 5 or the like, for example, without any specific limitations. In particular, a formyl group, an acetyl group, or a propionyl group is preferable as the acyl group that can constitute R³.

The alkyl ester group that can constitute R³ in formula (III) and formula (c) may be an alkyl ester group having a carbon number of 1 to 5 or the like, for example, without any specific limitations. In particular, a methyl ester group or an ethyl ester group is preferable as the alkyl ester group that can constitute R³.

The organic group including 5 or 7 fluorine atoms that can constitute R⁴ in formula (III) and formula (c) may be a fluoroalkyl group including 5 or 7 fluorine atoms, a fluoroalkoxyalkyl group including 5 or 7 fluorine atoms, a fluoroalkoxyalkenyl group including 5 or 7 fluorine atoms, or the like, for example, without any specific limitations.

The fluoroalkyl group including 5 or 7 fluorine atoms may be a 2,2,3,3,3-pentafluoropropyl group (number of fluorine atoms: 5; number of carbon atoms: 3), a 3,3,4,4,4-pentafluorobutyl group (number of fluorine atoms: 5; number of carbon atoms: 4), a 2,2,3,3,4,4,4-heptafluorobutyl group (number of fluorine atoms: 7; number of carbon atoms: 4), a 1,2,2,2-tetrafluoro-1-(trifluoromethyl)ethyl group (number of fluorine atoms: 7; number of carbon atoms: 3), or the like, for example. In particular, a 2,2,3,3,3-pentafluoropropyl group (number of fluorine atoms: 5; carbon number: 3) or a 2,2,3,3,4,4,4-heptafluorobutyl group (number of fluorine atoms: 7; carbon number: 4) is preferable, and a 2,2,3,3,3-pentafluoropropyl group (number of fluorine atoms: 5; carbon number: 3) is more preferable.

The fluoroalkoxyalkyl group including 5 or 7 fluorine atoms may be a pentafluoroethoxymethyl group (number of fluorine atoms: 5; number of carbon atoms: 3), a pentafluoroethoxyethyl group (number of fluorine atoms: 5; number of carbon atoms: 4), or the like, for example.

The fluoroalkoxyalkenyl group including 5 or 7 fluorine atoms may be a pentafluoroethoxyvinyl group (number of fluorine atoms: 5; number of carbon atoms: 4) or the like, for example.

Examples of the monomer (c) represented by formula (c) described above that can form the monomer unit (III) represented by formula (III) described above include, but are not specifically limited to, α-chloroacrylic acid fluoroalkyl esters such as 2,2,3,3,3-pentafluoropropyl α-chloroacrylate, 3,3,4,4,4-pentafluorobutyl α-chloroacrylate, 1,2,2,2-tetrafluoro-1-(trifluoromethyl)ethyl α-chloroacrylate, and 2,2,3,3,4,4,4-heptafluorobutyl α-chloroacrylate; α-chloroacrylic acid fluoroalkoxyalkyl esters such as pentafluoroethoxymethyl α-chloroacrylate and pentafluoroethoxyethyl α-chloroacrylate; and α-chloroacrylic acid fluoroalkoxyalkenyl esters such as pentafluoroethoxyvinyl α-chloroacrylate.

From a viewpoint of further improving main chain scission properties of the copolymer B upon irradiation with an electron beam or the like, the monomer unit (III) is preferably a structural unit that is derived from an α-chloroacrylic acid fluoroalkyl ester.

Note that although detailed description of the monomer unit (II) that can be included in the copolymer B is omitted here since it is the same as the monomer unit (II) that can be included in the copolymer A, α-methylstyrene is preferable as the monomer (b) represented by formula (b) described above that can form the monomer unit (II) in the copolymer B from a viewpoint of improving ease of production of the copolymer B and main chain scission properties of the copolymer B upon irradiation with an electron beam. In other words, the copolymer B preferably includes an α-methylstyrene unit.

Note that the proportion constituted by the monomer unit (II) among all monomer units of the copolymer B is not specifically limited and can be set as not less than 30 mol % and not more than 70 mol %, for example.

### <Properties of Copolymer B>

### [Weight-Average Molecular Weight (Mw)]

The weight-average molecular weight (Mw) of the copolymer B is preferably 10,000 or more, more preferably 12,000 or more, and even more preferably 14,000 or more, and is preferably 250,000 or less, more preferably 180,000 or less, and even more preferably 50,000 or less. When the weight-average molecular weight (Mw) of the copolymer B is not less than any of the lower limits set forth above, solubility of a resist film in a developer can be restricted from increasing excessively at a low irradiation dose. Moreover, when the weight-average molecular weight (Mw) of the copolymer B is not more than any of the upper limits set forth above, it is easy to prepare the positive resist composition.

### [Number-Average Molecular Weight (Mn)]

The number-average molecular weight (Mn) of the copolymer B is preferably 7,000 or more, and more preferably 10,000 or more, and is preferably 150,000 or less. When the number-average molecular weight of the copolymer B is not less than any of the lower limits set forth above, solubility of a resist film in a developer can be further restricted from increasing excessively at a low irradiation dose, and a resist pattern having further improved contrast can be formed. Moreover, when the number-average molecular weight of the copolymer B is not more than the upper limit set forth above, the positive resist composition is even easier to produce.

### [Molecular Weight Distribution (Mw/Mn)]

The molecular weight distribution (Mw/Mn) of the copolymer B is preferably 1.00 or more, and more preferably 1.10 or more, and is preferably 1.70 or less, and more preferably 1.65 or less. When the molecular weight distribution (Mw/Mn) of the copolymer B is not less than any of the lower limits set forth above, ease of production of the copolymer B can be increased. Moreover, when the molecular weight distribution (Mw/Mn) of the copolymer B is not more than any of the upper limits set forth above, the contrast of an obtained resist pattern can be further increased.

### [Production Method of Copolymer B]

A copolymer B that includes the monomer unit (III) and the monomer unit (II) described above can be produced by, for example, polymerizing a monomer composition that contains the monomer (c) and the monomer (b), and then collecting and optionally purifying the resultant copolymer. The polymerization method and the purification method are not specifically limited and can be the same as the polymerization method and the purification method of the copolymer A described above. Moreover, it is preferable to use a polymerization initiator in production of the copolymer B. For example, a polymerization initiator such as azobisisobutyronitrile can suitably be used.

### <Mass Proportion of Copolymer B Relative to Total Mass of Copolymer A and Copolymer B>

When the mass of the copolymer A in the presently disclosed positive resist composition is taken to be A and the mass of the copolymer B in the presently disclosed positive resist composition is taken to be B, a mass proportion (B/(A+B)×100%) of the copolymer B relative to total mass of the copolymer A and the copolymer B in the positive resist composition may be adjusted as appropriate in accordance with the thickness of a positive resist film formed by applying the positive resist composition onto a substrate without any specific limitations.

### <Solvent>

The solvent that is contained in the presently disclosed positive resist composition is not specifically limited so long as it is a solvent in which the copolymer A and the copolymer B described above can dissolve. For example, known solvents such as those described in JP5938536B1 can be used. Of such solvents, anisole, propylene glycol monomethyl ether acetate (PGMEA), cyclopentanone, cyclohexanone, or isoamyl acetate is preferable as the solvent from a viewpoint of obtaining a positive resist composition of suitable viscosity and improving coatability of the positive resist composition.

### <Production of Positive Resist Composition>

The positive resist composition can be produced by mixing the above-described copolymer A, copolymer B, solvent, and known additives that can optionally be used. The method of mixing is not specifically limited and may be mixing by a commonly known method. Moreover, production may be performed by filtering the mixture after mixing of components.

The total concentration of the copolymer A and the copolymer B contained in the positive resist composition is normally not less than 0.8 mass % and not more than 5 mass %, and preferably not less than 0.8 mass % and not more than 2.8 mass %.

### [Filtration]

No specific limitations are placed on the method by which the mixture is filtered. For example, the mixture can be filtered using a filter. The filter is not specifically limited and may, for example, be a filtration membrane based on a fluorocarbon, cellulose, nylon, polyester, hydrocarbon, or the like. In particular, from a viewpoint of effectively preventing impurities such as metals from becoming mixed into the positive resist composition from metal piping or the like that may be used in production of the copolymer A and the copolymer B, the constituent material of the filter is preferably nylon, polyethylene, polypropylene, a polyfluorocarbon such as polytetrafluoroethylene or Teflon® (Teflon is a registered trademark in Japan, other countries, or both), tetrafluoroethylene-perfluoroalkyl vinyl ether copolymer (PFA), nylon, a composite membrane of polyethylene and nylon, or the like. For example, a filter disclosed in U.S. Pat. No. 6,103,122A may be used as the filter. Moreover, the filter may be a commercially available product such as Zeta Plus® 40Q (Zeta Plus is a registered trademark in Japan, other countries, or both) produced by CUNO Incorporated. Furthermore, the filter may be a filter that contains a strongly cationic or weakly cationic ion exchange resin. The average particle diameter of the ion exchange resin is not specifically limited but is preferably not less than 2 μm and not more than 10 μm. Examples of cation exchange resins that may be used include a sulfonated phenol-formaldehyde condensate, a sulfonated phenol-benzaldehyde condensate, a sulfonated styrene-divinylbenzene copolymer, a sulfonated methacrylic acid-divinylbenzene copolymer, and other types of sulfo or carboxy group-containing polymers. In the cation exchange resin, H⁺ counter ions, NH₄⁺ counter ions, or alkali metal counter ions such as K⁺ or Na⁺ counter ions are provided. The cation exchange resin preferably includes hydrogen counter ions. One example of such a cation exchange resin is Microlite® PrCH (Microlite is a registered trademark in Japan, other countries, or both) produced by Purolite, which is a sulfonated styrene-divinylbenzene copolymer including H⁺ counter ions. Another example of such a cation exchange resin is commercially available as AMBERLYST® (AMBERLYST is a registered trademark in Japan, other countries, or both) produced by Rohm and Haas Company.

The pore diameter of the filter is preferably not less than 0.001 μm and not more than 1 μm. When the pore diameter of the filter is within the range set forth above, it is possible to sufficiently prevent impurities such as metals from being mixed into the positive resist composition.

The following describes, as one example, a method of forming a resist pattern using the presently disclosed positive resist composition.

### (Method of Forming Resist Pattern)

The method of forming a resist pattern using the presently disclosed positive resist composition can include, for example, a step of forming a resist film using the presently disclosed positive resist composition (resist film formation step), a step of exposing the resist film (exposure step), and a step of developing the resist film that has been exposed using a developer (development step). Moreover, this method may further include steps other than the resist film formation step, the exposure step, and the development step described above. Specifically, the method may include a step of forming a lower layer film on a substrate on which the resist film is to be formed (lower layer film formation step) in advance of the resist film formation step. Moreover, the method may include a step of heating the resist film that has been exposed (post exposure bake step) between the exposure step and the development step. Furthermore, the method may further include a step of removing the developer (rinsing step) after the development step. Also, the method may include a step of etching the lower layer film and/or the substrate (etching step) after a resist pattern has been formed. The following describes each of the steps in order.

### <Lower Layer Film Formation Step>

In the lower layer film formation step that can optionally be performed before the resist film formation step, a lower layer film is formed on a substrate. Through provision of the lower layer film on the substrate, the surface of the substrate is hydrophobized. This can increase affinity of the substrate and a resist film and can increase close adherence between the substrate and the resist film. The lower layer film may be an inorganic lower layer film or an organic lower layer film.

### —Substrate—

The substrate is not specifically limited and may, for example, be a mask blank including a light shielding layer formed on a substrate or a substrate including an electrically insulating layer and copper foil on the electrically insulating layer that is used in production of a printed board or the like.

The material of the substrate may, for example, be an inorganic material such as a metal (silicon, copper, chromium, iron, aluminum, etc.), glass, titanium oxide, silicon dioxide (SiO₂), silica, or mica; a nitride such as SiN; an oxynitride such as SiON; or an organic material such as acrylic, polystyrene, cellulose, cellulose acetate, or phenolic resin. Of these materials, a metal is preferable as the material of the substrate. By using a silicon substrate, a silicon dioxide substrate, or a copper substrate, and preferably a silicon substrate or a silicon dioxide substrate as the substrate, it is possible to form a structure having a cylinder structure.

No specific limitations are placed on the size and shape of the substrate. Note that the surface of the substrate may be smooth or may have a curved or irregular shape, and that a substrate having a flake shape or the like may be used.

Moreover, the surface of the substrate may be subjected to surface treatment as necessary. For example, in the case of a substrate having hydroxy groups in a surface layer thereof, the substrate can be surface treated using a silane coupling agent that can react with hydroxy groups. This makes it possible to convert the surface layer of the substrate from hydrophilic to hydrophobic and to increase close adherence between the substrate and a lower layer film or between the substrate and a resist layer. The silane coupling agent is not specifically limited but is preferably hexamethyldisilazane.

An inorganic lower layer film disposed on the substrate can be formed by, for example, applying an inorganic material onto the substrate and then performing firing or the like of the inorganic material. The inorganic material may be a silicon-based material or the like, for example.

An organic lower layer film disposed on the substrate can be formed by, for example, applying an organic material onto the substrate to form a coating film and then drying the coating film. The organic material is not limited to being a material that is sensitive to light or an electron beam and may be a resist material or resin material that is typically used in the field of semiconductors or the field of liquid crystals, for example. In particular, the organic material is preferably a material that can form an organic lower layer film that can be etched, and particularly dry etched. By using such an organic material, it is possible to etch the organic lower layer film using a pattern formed through processing of a resist film, and to thereby transfer the pattern to the lower layer film and form a lower layer film pattern. In particular, the organic material is preferably a material that can form an organic lower layer film that can be etched by oxygen plasma etching or the like. For example, AL412 produced by Brewer Science, Inc. or the like may be used as an organic material that is used to form an organic lower layer film.

Application of the organic material described above can be performed by spin coating or a conventional and commonly known method using a spinner or the like. The method by which the coating film is dried may be any method that can cause volatilization of solvent contained in the organic material. For example, a method in which baking is performed or the like may be adopted. Although no specific limitations are placed on the baking conditions, the baking temperature is preferably not lower than 80° C. and not higher than 300° C., and more preferably not lower than 200° C. and not higher than 300° C. Moreover, the baking time is preferably 30 seconds or more, and more preferably 60 seconds or more, and is preferably 500 seconds or less, more preferably 400 seconds or less, even more preferably 300 seconds or less, and particularly preferably 180 seconds or less. Furthermore, the thickness of the lower layer film after drying of the coating film is not specifically limited but is preferably not less than 10 nm and not more than 100 nm.

### <Resist Film Formation Step>

In the resist film formation step, the presently disclosed positive resist composition is applied onto a substrate that is to be processed using a resist pattern (onto a lower layer film in a case in which a lower layer film has been formed), and the applied positive resist composition is dried to form a resist film. Note that the substrate that is used in the resist film formation step is not specifically limited and can be the substrate that was described in the “Lower layer film formation step” section, for example.

The application method and the drying method of the positive resist composition can be methods that are typically used in the formation of a resist film without any specific limitations. In particular, application of the positive resist composition is preferably performed by spin coating. The spinning speed (rpm) in this application is not specifically limited and should be adjusted as appropriate such that the dried resist film has a specific thickness. Moreover, from a viewpoint of forming a uniform resist film, the spinning time is preferably 10 seconds or more, and more preferably 20 seconds or more. Furthermore, from a viewpoint of shortening operating time, the spinning time is preferably 120 seconds or less. The method of drying is preferably heating (prebaking). The prebaking temperature is preferably 80° C. or higher, and more preferably 100° C. or higher from a viewpoint of improving film density of the resist film, and is preferably 250° C. or lower, more preferably 220° C. or lower, and even more preferably 200° C. or lower from a viewpoint of reducing change of the molecular weight and molecular weight distribution of the copolymer A and the copolymer B in the resist film between before and after prebaking. Furthermore, the prebaking time is preferably 10 seconds or more, more preferably 20 seconds or more, and even more preferably 30 seconds or more from a viewpoint of improving film density of the resist film formed through prebaking, and is preferably 10 minutes or less, more preferably 5 minutes or less, and even more preferably 3 minutes or less from a viewpoint of reducing change of the molecular weight and molecular weight distribution of the copolymer A and the copolymer B in the resist film between before and after prebaking.

### <Exposure Step>

In the exposure step, the resist film formed in the resist film formation step is irradiated with ionizing radiation or the like (electron beam, EUV, etc.) to write a desired pattern. Note that irradiation with ionizing radiation or the like can be performed using a known writing tool such as an electron beam lithography tool or an EUV exposure tool.

### <Post Exposure Bake Step>

In the post exposure bake step that can optionally be performed, the resist film that has been exposed in the exposure step is heated. By performing the post exposure bake step, it is possible to reduce the surface roughness of a resist pattern.

The heating temperature is preferably 60° C. or higher, more preferably 70° C. or higher, and even more preferably 80° C. or higher, and is preferably 200° C. or lower, more preferably 170° C. or lower, and even more preferably 150° C. or lower. When the heating temperature is within any of the ranges set forth above, clarity of a resist pattern can be increased while also favorably reducing surface roughness of the resist pattern.

The time for which the resist film is heated (heating time) in the post exposure bake step is preferably 10 seconds or more, more preferably 20 seconds or more, and even more preferably 30 seconds or more. When the heating time is 10 seconds or more, clarity of a resist pattern can be further increased while also sufficiently reducing surface roughness of the resist pattern. On the other hand, the heating time is preferably 10 minutes or less, more preferably 5 minutes or less, and even more preferably 3 minutes or less, for example, from a viewpoint of production efficiency.

The method by which the resist film is heated in the post exposure bake step is not specifically limited and may, for example, be a method in which the resist film is heated by a hot plate, a method in which the resist film is heated in an oven, or a method in which hot air is blown against the resist film.

### <Development Step>

In the development step, the resist film that has been exposed (resist film that has been exposed and heated in a case in which the post exposure bake step is performed) is developed using a developer.

Development of the resist film can be performed by bringing the resist film into contact with the developer, for example. The method by which the resist film and the developer are brought into contact may be, but is not specifically limited to, a method using a known technique such as immersion of the resist film in the developer or application of the developer onto the resist film.

### <Developer>

The developer can be selected as appropriate depending on properties of the previously described copolymer A and copolymer B, for example. Specifically, in selection of the developer, it is preferable to select a developer that does not dissolve a resist film prior to the exposure step being performed but that can dissolve an exposed part of a resist film that has undergone the exposure step. One developer may be used individually, or two or more developers may be used as a mixture in a freely selected ratio.

Examples of developers that can be used include fluorinated solvents such as hydrofluorocarbons (1,1,1,2,3,4,4,5,5,5-decafluoropentane (CF₃CFHCFHCF₂CF₃), 1,1,1,2,2,3,3,4,4,5,5,6,6-tridecafluorohexane, 1,1,1,2,2,3,4,5,5,5-decafluoropentane, 1,1,1,3,3-pentafluorobutane, 1,1,1,2,2,3,3,4,4-nonafluorohexane, etc.), hydrochlorofluorocarbons (2,2-dichloro-1,1,1-trifluoroethane, 1,1-dichloro-1-fluoroethane, 1,1-dichloro-2,2,3,3,3-pentafluoropropane (CF₃CF₂CHCl₂), 1,3-dichloro-1,1,2,2,3-pentafluoropropane (CClF₂CF₂CHClF), etc.), hydrofluoroethers (methyl nonafluorobutyl ether (CF₃CF₂CF₂CF₂OCH₃), methyl nonafluoroisobutyl ether, ethyl nonafluorobutyl ether (CF₃CF₂CF₂CF₂OC₂H₅), ethyl nonafluoroisobutyl ether, perfluorohexyl methyl ether (CF₃CF₂CF(OCH₃)C₃F₇), etc.), and perfluorocarbons (CF₄, C₂F₆, C₃F₈, C₄F₈, C₄F₁₀, C₅F₁₂, C₆F₁₂, C₆F₁₄, C₇F₁₄, C₇F₁₆, C₈F₁₈, C₉F₂₀, etc.); alcohols such as methanol, ethanol, 1-propanol, 2-propanol (isopropyl alcohol), 1-butanol, 2-butanol, 1-pentanol, 2-pentanol, and 3-pentanol; acetic acid esters including an alkyl group such as amyl acetate and hexyl acetate; mixtures of a fluorinated solvent and an alcohol; mixtures of a fluorinated solvent and an acetic acid ester including an alkyl group; mixtures of an alcohol and an acetic acid ester including an alkyl group; and mixtures of a fluorinated solvent, an alcohol, and an acetic acid ester including an alkyl group. Of these developers, an alcohol such as 2-butanol or isopropyl alcohol is preferably used to perform development from a viewpoint of even further increasing the contrast of a resist pattern.

The temperature of the developer during development is not specifically limited and can be set as not lower than 5° C. and not higher than 40° C., for example. Moreover, the development time can be set as not less than 10 seconds and not more than 4 minutes, for example.

### <Rinsing Step>

In the rinsing step that can optionally be performed, the developer is removed after the development step. Removal of the developer can be performed using a rinsing liquid, for example.

Specific examples of rinsing liquids that may be used include the same liquids as the developers given as examples in the “Development step” section, and also hydrocarbon solvents such as octane and heptane, and water, for example. The rinsing liquid may contain a surfactant. In selection of the rinsing liquid, it is preferable to select a rinsing liquid that, compared to the developer used in the development step, has a lower tendency to dissolve the resist film prior to the exposure step being performed and that readily mixes with the developer.

The temperature of the rinsing liquid during rinsing is not specifically limited and can be set as not lower than 5° C. and not higher than 40° C., for example. Moreover, the rinsing time can be set as not less than 5 seconds and not more than 3 minutes, for example.

The developer and rinsing liquid described above may each be filtered prior to use. The filtration method may be a filtration method using a filter such as previously described in the “Production of positive resist composition” section, for example.

### <Etching Step>

In the etching step that can optionally be performed, etching of the lower layer film and/or the substrate is performed using the above-described resist pattern as a mask so as to form a pattern in the lower layer film and/or substrate.

The number of times that etching is performed is not specifically prescribed and may be once or a plurality of times. Moreover, the etching may be dry etching or wet etching, but is preferably dry etching. The dry etching can be performed using a commonly known dry etching apparatus. An etching gas that is used in the dry etching can be selected as appropriate depending on the element composition of the lower layer film or substrate that is to be etched, for example. Examples of etching gases that may be used include fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCl, NO, NH₃, and BCl₃; and inert gases such as He, N₂, and Ar. One of these gases may be used individually, or two or more of these gases may be used as a mixture. Note that dry etching of an inorganic lower layer film is usually performed using an oxygen-based gas. Moreover, dry etching of a substrate is normally performed using a fluorine-based gas and may suitably be performed using a mixture of a fluorine-based gas and an inert gas.

Lower layer film remaining on the substrate may be removed before etching of the substrate or after etching of the substrate as necessary. In a case in which the lower layer film is removed before etching of the substrate is performed, this lower layer film may be a lower layer film in which a pattern is formed or may be a lower layer film in which a pattern is not formed.

The method by which the lower layer film is removed may, for example, be dry etching such as described above. In the case of an inorganic lower layer film, the lower layer film may be removed by bringing a liquid such as a basic liquid or an acidic liquid, and preferably a basic liquid into contact with the lower layer film. The basic liquid is not specifically limited and may be alkaline hydrogen peroxide aqueous solution or the like, for example. The method by which the lower layer film is removed through wet stripping using alkaline hydrogen peroxide aqueous solution is not specifically limited so long as it is a method in which the lower layer film and alkaline hydrogen peroxide aqueous solution can be brought into contact under heated conditions for a specific time and may, for example, be a method in which the lower layer film is immersed in heated alkaline hydrogen peroxide aqueous solution, a method in which alkaline hydrogen peroxide aqueous solution is sprayed against the lower layer film in a heated environment, or a method in which heated alkaline hydrogen peroxide aqueous solution is applied onto the lower layer film. After any of these methods is performed, the substrate may be washed with water and then dried to thereby obtain a substrate from which the lower layer film has been removed.

The following describes one example of a method of forming a resist pattern using the presently disclosed positive resist and a method of etching a lower layer film and a substrate using a resist pattern that is formed. However, since the substrate, conditions of each step, and so forth in the following example can be the same as the substrate, conditions of each step, and so forth described above, description thereof is omitted below.

The one example of a method of forming a resist pattern is a method of forming a resist pattern using EUV that includes the previously described lower layer film formation step, resist film formation step, exposure step, development step, and rinsing step. Moreover, the one example of an etching method is a method in which a resist pattern formed by the method of forming a resist pattern is used as a mask and that includes an etching step.

Specifically, in the lower layer film formation step, an inorganic material is applied onto a substrate and is fired to form an inorganic lower layer film.

Next, in the resist film formation step, the presently disclosed positive resist composition is applied onto the inorganic lower layer film that has been formed in the lower layer film formation step and is dried to form a resist film.

The resist film that is formed in the resist film formation step is then irradiated with EUV in the exposure step so as to write a desired pattern.

Moreover, in the development step, the resist film that has been exposed in the exposure step and a developer are brought into contact to develop the resist film and form a resist pattern on the lower layer film.

In the rinsing step, the resist film that has been developed in the development step and a rinsing liquid are brought into contact to rinse the developed resist film.

In the etching step, the resist pattern is used as a mask to etch the lower layer film and thereby form a pattern in the lower layer film.

The lower layer film in which the pattern has been formed is then used as a mask to etch the substrate and thereby form a pattern in the substrate.

### (Etching Resistance of Resist Film)

A resist film obtained by the method of forming a resist pattern using the presently disclosed positive resist composition has excellent etching resistance, and, in particular, has excellent dry etching resistance. Note that the dry etching resistance of the resist film tends to be better when the carbon content per unit volume of the copolymer A and the copolymer B contained in the positive resist composition is higher.

Through the method of forming a resist pattern using the presently disclosed positive resist composition, it is possible to obtain a laminate including a resist film having a two-layer structure such as described below, for example.

### (Laminate)

A laminate obtained by the method of forming a resist pattern using the presently disclosed positive resist composition may include a substrate and a resist film formed on the substrate, for example, wherein the resist film includes a lower layer that is disposed on the substrate and an upper layer that is disposed on the lower layer. Moreover, the lower layer is formed from the previously described copolymer A, and the upper layer is formed from the previously described copolymer B.

### EXAMPLES

The following provides a more specific description of the present disclosure based on examples. However, the present disclosure is not limited to the following examples.

In the examples and comparative examples, the following methods were used to measure the number-average molecular weight, weight-average molecular weight, and molecular weight distribution of a copolymer, and surface free energy.

### <Number-Average Molecular Weight, Weight-Average Molecular Weight, and Molecular Weight Distribution>

For each obtained copolymer A or copolymer B, the number-average molecular weight (Mn) and weight-average molecular weight (Mw) of the copolymer were measured by gel permeation chromatography, and then the molecular weight distribution (Mw/Mn) of the copolymer was calculated.

Specifically, the number-average molecular weight (Mn) and weight-average molecular weight (Mw) of each copolymer A or copolymer B were determined as standard polystyrene-equivalent values with tetrahydrofuran as an eluent solvent using a gel permeation chromatograph (HLC-8220 produced by Tosoh Corporation). The molecular weight distribution (Mw/Mn) was then calculated. Note that each obtained copolymer A or copolymer B was confirmed to not substantially contain a component having a weight-average molecular weight (Mw) of less than 1,000.

### <Surface Free Energy>

### <<Surface Free Energy of Copolymer A>>

A copolymer A1 produced as a copolymer A in Production Example 1 was dissolved in isoamyl acetate to produce a composition (A) for surface free energy measurement having a concentration of 3 mass %. The obtained composition (A) was used to produce a film by the following method.

### <<Production Method of Film>>

A spin coater (MS-A150 produced by Mikasa Co., Ltd.) was used to apply the composition (A) produced as described above onto a silicon wafer of 4 inches in diameter such as to have a thickness of 50 nm. The applied composition (A) was heated for 1 minute by a hot plate having a temperature of 170° C. to form a resist film on the silicon wafer.

Next, under the following conditions, a goniometer (Drop Master 700 produced by Kyowa Interface Science Co., Ltd.) was used to measure the contact angle with respect to the obtained film for two solvents (water and diiodomethane) for which surface tension, a polar component (p), and a dispersive force component (d) were known. Surface free energy was evaluated by the Owens-Wendt method (extended Fowkes model) to calculate the surface free energy of the film. The determined surface free energy of the film was taken to be the surface free energy of the copolymer A. The result is shown in Table 1.

### <<Measurement Conditions of Contact Angle Measurement>>

Needle: Metal needle 22 G (water), Teflon® coated needle 22 G (diiodomethane)

Wait time: 1,000 ms

Liquid volume: 1.8 μL

Liquid landing recognition: Water 50 dat, diiodomethane 100 dat

Temperature: 23° C.

### <<Surface Free Energy of Copolymer B>>

The surface free energy of a copolymer B was determined in the same way as in calculation of the surface free energy of a copolymer A with the exception that B1 to B4 produced as copolymers B in Production Examples 2 to 5 were used instead of the copolymer A. The results are shown in Table 1.

### <<Surface Free Energy of Positive Resist Composition>>

The surface free energy of a resist film formed using a positive resist composition produced in each example or comparative example was determined in the same way as in calculation of the surface free energy of a copolymer A with the exception that the positive resist composition produced in that example or comparative example was used instead of the composition (A). The determined surface free energy of the resist film was taken to be the surface free energy of the positive resist composition.

### <Production of Copolymer A>

### Production Example 1: Production of Copolymer A1

### [Production of 18% Solid Content Aqueous Solution of Partially Hydrogenated Tallow Fatty Acid Potassium Soap]

After preparing 100 g of deionized water and then heating this deionized water to 70° C. under stirring, 8.40 g of potassium hydroxide (49% aqueous solution) was added thereto. Next, 19.6 g of HARDENED TALLOW FATTY ACID 45° HFA (produced by NOF Corporation) was added at an addition rate of 1.28 g/min, and then 0.126 g of potassium silicate was added. At least 2 hours of stirring was performed at 80° C. to yield an 18% solid content aqueous solution of partially hydrogenated tallow fatty acid potassium soap.

### [Synthesis of Polymerized Product]

A glass ampoule in which a stirrer had been placed was charged with 3.000 g of 1-phenyl-1-trifluoromethyl-2,2,2-trifluoroethyl α-chloroacrylate (ACAFPh) as a monomer (a) and 1.066 g of α-methylstyrene as a monomer (b). In addition, 6.771 g of deionized water relative to 0.546 g of the 18% solid content aqueous solution of partially hydrogenated tallow fatty acid potassium soap produced as described above was added into the same ampoule to obtain a monomer composition, and then the ampoule was tightly sealed and oxygen was removed from the system through 10 repetitions of pressurization and depressurization with nitrogen gas.

The system was then heated to 75° C. and a polymerization reaction was carried out for 1 hour. Next, 10 g of tetrahydrofuran (THF) was added to the system and then the resultant solution was added dropwise to 100 g of a mixed solvent of THF and methanol (MeOH) (THF:MeOH (mass ratio)=33:67) to cause precipitation of a polymerized product. Thereafter, the polymerized product that had precipitated was collected by filtration. Note that the obtained polymerized product was a copolymer comprising 54 mol % of 1-phenyl-1-trifluoromethyl-2,2,2-trifluoroethyl α-chloroacrylate units and 46 mol % of α-methylstyrene units.

### [Purification of Polymerized Product]

The polymerized product that had been collected by filtration was subsequently dissolved in 10 g of THF and then the resultant solution was added dropwise to 100 g of a mixed solvent of THF and MeOH (THF:MeOH (mass ratio)=33:67) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer A1 (copolymer comprising 54 mol % of 1-phenyl-1-trifluoromethyl-2,2,2-trifluoroethyl α-chloroacrylate units and 46 mol % of α-methylstyrene units) as a copolymer A.

The number-average molecular weight (Mn) and weight-average molecular weight (Mw) of the obtained copolymer A1 were measured, and the molecular weight distribution (Mw/Mn) thereof was calculated. Moreover, the surface free energy of the copolymer A1 was determined. The results are shown in Table 1.

### <Production of Copolymer B>

### Production Example 2: Production of copolymer B1

### [Synthesis of Polymerized Product]

A monomer composition containing 3.000 g of 2,2,3,3,3-pentafluoropropyl α-chloroacrylate (ACAPFP) as a monomer (c), 3.476 g of α-methylstyrene as a monomer (b), 0.055 g of azobisisobutyronitrile as a polymerization initiator, and 1.621 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was then added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

### [Purification of Polymerized Product]

Next, the obtained polymerized product was dissolved in 10 g of THF and then the resultant solution was added dropwise to 100 g of a mixed solvent of THF and MeOH (THF:MeOH (mass ratio)=6:94) to cause precipitation of a white coagulated material (copolymer comprising 2,2,3,3,3-pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of α-methylstyrene units) as a copolymer B1.

Various measurements were performed with respect to the obtained copolymer B1 in the same way as in Production Example 1. The results are shown in Table 1.

### Production Example 3: Production of Copolymer B2

### [Synthesis of Polymerized Product]

A monomer composition containing 3.000 g of 2,2,3,3,4,4,4-heptafluorobutyl α-chloroacrylate (ACAHFB) as a monomer (c), 2.874 g of α-methylstyrene as a monomer (b), 0.046 g of azobisisobutyronitrile as a polymerization initiator, and 1.480 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

### [Purification of Polymerized Product]

Next, the obtained polymerized product was dissolved in 10 g of THF and then the resultant solution was added dropwise to 100 g of a mixed solvent of THF and MeOH (THF:MeOH (mass ratio)=9:91) to cause precipitation of a white coagulated material (copolymer comprising 2,2,3,3,4,4,4-heptafluorobutyl α-chloroacrylate units and α-methylstyrene units). The solution containing the precipitated coagulated material was subsequently filtered using a Kiriyama funnel to obtain a white acrylic polymer (polymer comprising 50 mol % of 2,2,3,3,4,4,4-heptafluorobutyl α-chloroacrylate units and 50 mol % of α-methylstyrene units) as a copolymer B2.

Various measurements were performed with respect to the obtained copolymer B2 in the same way as in Production Example 1. The results are shown in Table 1.

### Production Example 4: Production of Copolymer B3

### [Synthesis of Polymerized Product]

A white coagulated material (polymerized product) was obtained by performing operations in the same way as in Production Example 2 with the exception that the amount of azobisisobutyronitrile as a polymerization initiator was changed to 0.110 g. Note that the obtained polymerized product was a copolymer comprising 50 mol % of 2,2,3,3,3-pentafluoropropyl α-chloroacrylate units and 50 mol % of α-methylstyrene units.

### [Purification of Polymerized Product]

Next, the obtained polymerized product was dissolved in 10 g of THF and then the resultant solution was added dropwise to 100 g of a mixed solvent of THF and MeOH (THF:MeOH (mass ratio)=5:95) to cause precipitation of a white coagulated material (copolymer comprising 2,2,3,3,3-pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of α-methylstyrene units).

Various measurements were performed with respect to the obtained copolymer in the same way as in Production Example 1. The results are shown in Table 1.

### Production Example 5: Production of Copolymer B4

### [Synthesis of Polymerized Product]

A white coagulated material (polymerized product) was obtained by performing operations in the same way as in Production Example 2 with the exception that the amount of azobisisobutyronitrile as a polymerization initiator was changed to 0.006 g. Note that the obtained polymerized product was a copolymer comprising 50 mol % of 2,2,3,3,3-pentafluoropropyl α-chloroacrylate units and 50 mol % of α-methylstyrene units.

### [Purification of Polymerized Product]

Next, the obtained polymerized product was dissolved in 10 g of THF and then the resultant solution was added dropwise to 100 g of a mixed solvent of THF and MeOH (THF:MeOH (mass ratio)=15:85) to cause precipitation of a white coagulated material (copolymer comprising 2,2,3,3,3-pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of α-methylstyrene units).

Various measurements were performed with respect to the obtained copolymer in the same way as in Production Example 1. The results are shown in Table 1.

TABLE 1

| | | Copolymer A | Copolymer B | | | |
|---|---|---|---|---|---|---|
| | | A | B1 | B2 | B3 | B4 |
| Polymerization method | | Emulsion | Solution | Solution | Solution | Solution |
| | | polymerization | polymerization | polymerization | polymerization | polymerization |
| Monomers | ACAFPh [g] | 3.000 | — | — | — | — |
| | ACAPFP [g] | — | 3.000 | — | 3.000 | 3.000 |
| | ACAHFB [g] | — | — | 3.000 | — | — |
| | α-Methylstyrene [g] | 1.066 | 3.476 | 2.874 | 3.476 | 3.476 |
| Polymerization initiator | Azobisisobutyronitrile [g] | — | 0.055 | 0.046 | 0.110 | 0.006 |
| Solvent | Cyclopentanone [g] | — | 1.621 | 1.480 | 1.621 | 1.621 |
| | KORR (18%) soap [g] | 0.546 | — | — | — | — |
| | Deionized water [g] | 6.771 | — | — | — | — |
| Reaction conditions | Time [hr] | 1 | 6 | 6 | 6 | 6 |
| | Temperature [° C.] | 75 | 78 | 78 | 78 | 78 |
| Solvent used in precipitation | THF:MeOH | 33:67 | 0:100 | 0:100 | 0:100 | 0:100 |
| of polymerized product | (mass ratio) [—] | | | | | |
| Solvent used in purification of | THF:MeOH | 33:67 | 6:94 | 9:91 | 5:95 | 15:85 |
| polymerized product | (mass ratio) [—] | | | | | |
| Physical properties of | Number-average | 267588 | 19556 | 18461 | 13430 | 35806 |
| copolymer | molecular weight (Mn) [—] | | | | | |
| | Weight-average molecular | 363867 | 24943 | 25273 | 16049 | 49556 |
| | weight (Mw) [—] | | | | | |
| | Molecular weight | 1.360 | 1.275 | 1.369 | 1.195 | 1.384 |
| | distribution (Mw/Mn) [—] | | | | | |
| | Surface free energy | 31.0 | 24.2 | 21.2 | 24.2 | 24.2 |
| | [mJ/m²] | | | | | |

In Table 1:
“ACAFPh” represents 1-phenyl-1-trifluoromethyl-2,2,2-trifluoroethyl α-chloroacrylate;
“ACAPFP” represents 2,2,3,3,3-pentafluoropropyl α-chloroacrylate;
“ACAHFB” represents 2,2,3,3,4,4,4-heptafluorobutyl α-chloroacrylate;
“KORR (18%) soap” represents 18% solid content aqueous solution of partially hydrogenated tallow fatty acid potassium soap;
“MeOH” represents methanol; and
“THF” represents tetrahydrofuran.

### Example 1

### <Production of Positive Resist Composition>

The copolymer A1 was used as a copolymer A and the copolymer B1 was used as a copolymer B. The copolymer A1 and the copolymer B1 were dissolved in isoamyl acetate (boiling point: 142° C.) as a solvent such that a mass proportion of the copolymer B relative to total mass of the copolymer A and the copolymer B in a positive resist composition was 50%. Thus, a positive resist composition of 2 mass % in concentration that contained a copolymer A and a copolymer B was produced.

### <Eth>

The positive resist composition produced as described above was dripped by a dropper onto a silicon wafer of 4 inches in diameter that was set in a spin coater (MS-A150 produced by Mikasa Co., Ltd.), and the silicon wafer was spun with a spinning speed of 7,000 rpm and a spinning time of 60 seconds. The silicon wafer was then placed on a hot plate and was heated at a temperature of 170° C. for 1 minute to form a resist film of 20 nm in thickness (resist film formation step).

An electron beam lithography tool (ELS-S50 produced by Elionix Inc.) was used to write a plurality of patterns (dimensions: 500 μm×500 μm) over the resist film with different electron beam irradiation doses (exposure step). The resist film that had been exposed was then heated for 1 minute using a 100° C. hot plate (post exposure bake step). The resist film that had been heated was then immersed in isopropyl alcohol (IPA) as a resist developer at 23° C. for 1 minute to perform development (development step). Thereafter, the developer was removed by nitrogen blowing.

Note that the electron beam irradiation dose was varied in a range of 4 μC/cm² to 200 μC/cm² in increments of 4 μC/cm². Next, an optical film thickness measurement tool (Lambda Ace produced by SCREEN Semiconductor Solutions Co., Ltd.) was used to measure the thickness of the resist film in regions in which writing had been performed. A sensitivity curve was prepared that indicated a relationship between the common logarithm of the total electron beam irradiation dose and the remaining film fraction of the resist film after development (=thickness of resist film after development/thickness of resist film formed on silicon wafer).

With respect to the obtained sensitivity curve (horizontal axis: common logarithm of total electron beam irradiation dose; vertical axis: remaining film fraction of resist film (0≤remaining film fraction≤1.00)), the sensitivity curve was fitted to a quadratic function in a range from a remaining film fraction of 0.20 to a remaining film fraction of 0.80. A straight line (linear approximation for gradient of sensitivity curve) was then prepared that joined points on the obtained quadratic function (function of remaining film fraction and common logarithm of total irradiation dose) corresponding to remaining film fractions of 0 and 0.50.

The total electron beam irradiation dose Eₜₕ (μC/cm²) corresponding to a remaining film fraction of 0 on the obtained straight line (linear approximation of gradient of sensitivity curve) was determined.

### <Remaining Film Fraction>

The resist film formation step described above in the “Eth” section was performed to form a positive resist film of 20 nm in thickness. The same electron beam lithography tool as described above in the “Eth” section was then used to perform electron beam writing of a 1:1 line-and-space pattern having a line width of 25 nm (i.e., a half pitch of 25 nm) with an optimal exposure dose (Eₒₚ) so as to obtain an electron beam-written wafer. Note that the optimal exposure dose (Eₒₚ) was set as appropriate with a value approximately double the total electron beam irradiation dose Eₜₕ corresponding to a remaining film fraction of 0 on the linear approximation of the gradient of the sensitivity curve as a rough guide.

The electron beam-written wafer was immersed in isopropyl alcohol as a resist developer at 23° C. for 1 minute to perform development treatment. Thereafter, the developer was removed by nitrogen blowing to form a line-and-space pattern (half-pitch: 25 nm). A pattern section was then cleaved and was observed at ×100,000 magnification using a scanning electron microscope (JSM-7800F PRIME produced by JEOL Ltd.) in order to measure the maximum height (Tₘₐₓ) of the resist pattern after development and the initial thickness T₀ of the resist film. The “remaining film fraction (half-pitch (hp): 25 nm)” was determined by the following formula (3). The remaining film fraction was then evaluated in accordance with the following standard. The result is shown in Table 2. A higher remaining film fraction (half-pitch (hp): 25 nm) indicates less resist pattern top loss.

$$Remaining film fraction ( \% ) = ( {T}_{max} / {T}_{0} ) \times 100 \qquad ( 3 )$$

A: More than 99.5%

B: More than 99.0% and not more than 99.5%

C: 99.0% or less

### <Ratio of Coverage of Copolymer B>

A ratio of coverage of the copolymer B was calculated in accordance with the following formula (4). The result is shown in Table 2.

$$Ratio of coverage of copolymer B = [ ( a - c ) / ( a - b ) ] \times 100 \qquad ( 4 )$$

(In formula (4), a represents the surface free energy of the copolymer A, b represents the surface free energy of the copolymer B, and c represents the surface free energy of the positive resist composition.)

A higher ratio of coverage of the copolymer B indicates that in a resist film formed using the positive resist composition, the copolymer B is localized in an upper layer of the resist film.

### <Remaining Residues>

The resist pattern formed in evaluation of the remaining film fraction described above was observed using a scanning electron microscope (SEM) at ×100,000 magnification, and the degree to which residues remained in the resist pattern was evaluated in accordance with the following standard. Note that a residue remaining in a resist pattern can be confirmed as a “dot” or the like having high brightness in an SEM image compared to a line pattern region where a residue is not attached.

A: Residues not observed in resist pattern having half-pitch (hp) of 25 nm

B: Residues observed in very small amount that is within permissible range in resist pattern having half-pitch (hp) of 25 nm

C: Residues observed in large amount that is not within permissible range in resist pattern having half-pitch (hp) of 25 nm

### Examples 2 to 5 and Comparative Examples 1 to 5

The mass proportion of the copolymer B relative to total mass of the copolymer A and the copolymer B in the positive resist composition was changed to 45% (Example 2), 40% (Example 3), 35% (Example 4), 30% (Example 5), 25% (Comparative Example 1), 20% (Comparative Example 2), 15% (Comparative Example 3), 10% (Comparative Example 4), or 5% (Comparative Example 5). With the exception of the above, operations and evaluations were performed in the same way as in Example 1. The results are shown in Table 2.

TABLE 2

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 1 | A1 | B1 | 20 | 50 | 100 | A | B |
| Example 2 | A1 | B1 | | 45 | 100 | A | A |
| Example 3 | A1 | B1 | | 40 | 100 | A | A |
| Example 4 | A1 | B1 | | 35 | 100 | B | A |
| Example 5 | A1 | B1 | | 30 | 99.9 | B | A |
| Comparative | A1 | B1 | | 25 | 97.7 | C | A |
| Example 1 | | | | | | | |
| Comparative | A1 | B1 | | 20 | 95.6 | C | A |
| Example 2 | | | | | | | |
| Comparative | A1 | B1 | | 15 | 93.4 | C | A |
| Example 3 | | | | | | | |
| Comparative | A1 | B1 | | 10 | 91.3 | C | A |
| Example 4 | | | | | | | |
| Comparative | A1 | B1 | | 5 | 89.1 | C | A |
| Example 5 | | | | | | | |

### Examples 6 to 12 and Comparative Examples 6 to 8

The mass proportion of the copolymer B relative to total mass of the copolymer A and the copolymer B in the positive resist composition was changed to 50% (Example 6), 45% (Example 7), 40% (Example 8), 35% (Example 9), 30% (Example 10), 25% (Example 11), 20% (Example 12), 15% (Comparative Example 6), 10% (Comparative Example 7), or 5% (Comparative Example 8). Moreover, the spinning speed was changed to 4,200 rpm, and the thickness of the formed resist film was set as 30 nm. With the exception of the above, operations and evaluations were performed in the same way as in Example 1. The results are shown in Table 3.

TABLE 3

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 6 | A1 | B1 | 30 | 50 | 100 | A | B |
| Example 7 | A1 | B1 | | 45 | 100 | A | B |
| Example 8 | A1 | B1 | | 40 | 100 | A | A |
| Example 9 | A1 | B1 | | 35 | 100 | A | A |
| Example 10 | A1 | B1 | | 30 | 100 | A | A |
| Example 11 | A1 | B1 | | 25 | 100 | B | A |
| Example 12 | A1 | B1 | | 20 | 99.9 | B | A |
| Comparative | A1 | B1 | | 15 | 96.6 | C | A |
| Example 6 | | | | | | | |
| Comparative | A1 | B1 | | 10 | 93.4 | C | A |
| Example 7 | | | | | | | |
| Comparative | A1 | B1 | | 5 | 90.2 | C | A |
| Example 8 | | | | | | | |

### Examples 13 to 20 and Comparative Examples 9 and 10

The mass proportion of the copolymer B relative to total mass of the copolymer A and the copolymer B in the positive resist composition was changed to 50% (Example 13), 45% (Example 14), 40% (Example 15), 35% (Example 16), 30% (Example 17), 25% (Example 18), 20% (Example 19), 15% (Example 20), 10% (Comparative Example 9), or 5% (Comparative Example 10). Moreover, the spinning speed was changed to 2,700 rpm, and the thickness of the formed resist film was set as 40 nm. With the exception of the above, operations and evaluations were performed in the same way as in Example 1. The results are shown in Table 4.

TABLE 4

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 13 | A1 | B1 | 40 | 50 | 100 | A | C |
| Example 14 | A1 | B1 | | 45 | 100 | A | B |
| Example 15 | A1 | B1 | | 40 | 100 | A | B |
| Example 16 | A1 | B1 | | 35 | 100 | A | A |
| Example 17 | A1 | B1 | | 30 | 100 | A | A |
| Example 18 | A1 | B1 | | 25 | 100 | A | A |
| Example 19 | A1 | B1 | | 20 | 100 | B | A |
| Example 20 | A1 | B1 | | 15 | 99.9 | B | A |
| Comparative | A1 | B1 | | 10 | 95.6 | C | A |
| Example 9 | | | | | | | |
| Comparative | A1 | B1 | | 5 | 91.3 | C | A |
| Example 10 | | | | | | | |

### Examples 21 to 28 and Comparative Examples 11 and 12

The mass proportion of the copolymer B relative to total mass of the copolymer A and the copolymer B in the positive resist composition was changed to 50% (Example 21), 45% (Example 22), 40% (Example 23), 35% (Example 24), 30% (Example 25), 25% (Example 26), 20% (Example 27), 15% (Example 28), 10% (Comparative Example 11), or 5% (Comparative Example 12). Moreover, the spinning speed was changed to 1,900 rpm, and the thickness of the formed positive resist film was set as 50 nm. With the exception of the above, operations and evaluations were performed in the same way as in Example 1. The results are shown in Table 5.

TABLE 5

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 21 | A1 | B1 | 50 | 50 | 100 | A | C |
| Example 22 | A1 | B1 | | 45 | 100 | A | C |
| Example 23 | A1 | B1 | | 40 | 100 | A | C |
| Example 24 | A1 | B1 | | 35 | 100 | A | B |
| Example 25 | A1 | B1 | | 30 | 100 | A | A |
| Example 26 | A1 | B1 | | 25 | 100 | A | A |
| Example 27 | A1 | B1 | | 20 | 100 | A | A |
| Example 28 | A1 | B1 | | 15 | 100 | A | A |
| Comparative | A1 | B1 | | 10 | 97.7 | C | A |
| Example 11 | | | | | | | |
| Comparative | A1 | B1 | | 5 | 92.3 | C | A |
| Example 12 | | | | | | | |

### Examples 29 to 37 and Comparative Example 13

The mass proportion of the copolymer B relative to total mass of the copolymer A and the copolymer B in the positive resist composition was changed to 50% (Example 29), 45% (Example 30), 40% (Example 31), 35% (Example 32), 30% (Example 33), 25% (Example 34), 20% (Example 35), 15% (Example 36), 10% (Example 37), or 5% (Comparative Example 13). Moreover, the spinning speed was changed to 1,200 rpm, and the thickness of the formed resist film was set as 60 nm. With the exception of the above, operations and evaluations were performed in the same way as in Example 1. The results are shown in Table 6.

TABLE 6

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 29 | A1 | B1 | 60 | 50 | 100 | A | C |
| Example 30 | A1 | B1 | | 45 | 100 | A | C |
| Example 31 | A1 | B1 | | 40 | 100 | A | C |
| Example 32 | A1 | B1 | | 35 | 100 | A | C |
| Example 33 | A1 | B1 | | 30 | 100 | A | B |
| Example 34 | A1 | B1 | | 25 | 100 | A | A |
| Example 35 | A1 | B1 | | 20 | 100 | A | A |
| Example 36 | A1 | B1 | | 15 | 100 | A | A |
| Example 37 | A1 | B1 | | 10 | 99.9 | B | A |
| Comparative | A1 | B1 | | 5 | 93.4 | C | A |
| Example 13 | | | | | | | |

### Examples 38 to 46 and Comparative Example 14

The mass proportion of the copolymer B relative to total mass of the copolymer A and the copolymer B in the positive resist composition was changed to 50% (Example 38), 45% (Example 39), 40% (Example 40), 35% (Example 41), 30% (Example 42), 25% (Example 43), 20% (Example 44), 15% (Example 45), 10% (Example 46), or 5% (Comparative Example 14). Moreover, the spinning speed was changed to 700 rpm, and the thickness of the formed resist film was set as 70 nm. With the exception of the above, operations and evaluations were performed in the same way as in Example 1. The results are shown in Table 7.

TABLE 7

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 38 | A1 | B1 | 70 | 50 | 100 | A | C |
| Example 39 | A1 | B1 | | 45 | 100 | A | C |
| Example 40 | A1 | B1 | | 40 | 100 | A | C |
| Example 41 | A1 | B1 | | 35 | 100 | A | C |
| Example 42 | A1 | B1 | | 30 | 100 | A | C |
| Example 43 | A1 | B1 | | 25 | 100 | A | B |
| Example 44 | A1 | B1 | | 20 | 100 | A | A |
| Example 45 | A1 | B1 | | 15 | 100 | A | A |
| Example 46 | A1 | B1 | | 10 | 100 | B | A |
| Comparative | A1 | B1 | | 5 | 94.5 | C | A |
| Example 14 | | | | | | | |

### Examples 47 to 55 and Comparative Example 15

The mass proportion of the copolymer B relative to total mass of the copolymer A and the copolymer B in the positive resist composition was changed to 50% (Example 47), 45% (Example 48), 40% (Example 49), 35% (Example 50), 30% (Example 51), 25% (Example 52), 20% (Example 53), 15% (Example 54), 10% (Example 55), or 5% (Comparative Example 15). Moreover, the spinning speed was changed to 400 rpm, and the thickness of the formed resist film was set as 80 nm. With the exception of the above, operations and evaluations were performed in the same way as in Example 1. The results are shown in Table 8.

TABLE 8

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 47 | A1 | B1 | 80 | 50 | 100 | A | C |
| Example 48 | A1 | B1 | | 45 | 100 | A | C |
| Example 49 | A1 | B1 | | 40 | 100 | A | C |
| Example 50 | A1 | B1 | | 35 | 100 | A | C |
| Example 51 | A1 | B1 | | 30 | 100 | A | C |
| Example 52 | A1 | B1 | | 25 | 100 | A | C |
| Example 53 | A1 | B1 | | 20 | 100 | A | B |
| Example 54 | A1 | B1 | | 15 | 100 | A | A |
| Example 55 | A1 | B1 | | 10 | 100 | B | A |
| Comparative | A1 | B1 | | 5 | 95.6 | C | A |
| Example 15 | | | | | | | |

The results of Examples 1 to 55 and Comparative Examples 1 to 15 are summarized in FIG. 1. In FIG. 1, the vertical axis indicates the mass proportion [B/(A+B)×100(%)] of the copolymer B relative to total mass of the copolymer A and the copolymer B in the positive resist composition, and the horizontal axis indicates the thickness [T nm] of the positive resist film. Moreover, in FIG. 1, “white circles” indicate an evaluation result of “B” or better for remaining film fraction and a ratio of coverage of the copolymer B of 99% or more, “black circles” indicate an evaluation result of “B” or better for both remaining film fraction and remaining residues and a ratio of coverage of the copolymer B of 99% or more, and “crosses” indicate an evaluation result of “C” for remaining film fraction.

### Examples 56 to 60 and Comparative Examples 16 to 20

B2 was used instead of B1 as a copolymer B. Moreover, the mass proportion of the copolymer B relative to total mass of the copolymer A and the copolymer B in the positive resist composition was changed to 50% (Example 56), 45% (Example 57), 40% (Example 58), 35% (Example 59), 30% (Example 60), 25% (Comparative Example 16), 20% (Comparative Example 17), 15% (Comparative Example 18), 10% (Comparative Example 19), or 5% (Comparative Example 20). With the exception of the above, operations and evaluations were performed in the same way as in Example 1. The results are shown in Table 9.

TABLE 9

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 56 | A1 | B2 | 20 | 50 | 100 | A | B |
| Example 57 | A1 | B2 | | 45 | 100 | A | B |
| Example 58 | A1 | B2 | | 40 | 100 | A | A |
| Example 59 | A1 | B2 | | 35 | 99.9 | B | A |
| Example 60 | A1 | B2 | | 30 | 99.6 | B | A |
| Comparative | A1 | B2 | | 25 | 98.4 | C | A |
| Example 16 | | | | | | | |
| Comparative | A1 | B2 | | 20 | 97.1 | C | A |
| Example 17 | | | | | | | |
| Comparative | A1 | B2 | | 15 | 95.8 | C | A |
| Example 18 | | | | | | | |
| Comparative | A1 | B2 | | 10 | 94.6 | C | A |
| Example 19 | | | | | | | |
| Comparative | A1 | B2 | | 5 | 93.3 | C | A |
| Example 20 | | | | | | | |

### Examples 61 to 67 and Comparative Examples 21 to 23

B2 was used instead of B1 as a copolymer B. Moreover, the mass proportion of the copolymer B relative to total mass of the copolymer A and the copolymer B in the positive resist composition was changed to 50% (Example 61), 45% (Example 62), 40% (Example 63), 35% (Example 64), 30% (Example 65), 25% (Example 66), 20% (Example 67), 15% (Comparative Example 21), 10% (Comparative Example 22), or 5% (Comparative Example 23). Furthermore, the spinning speed was changed to 4,200 rpm, and the thickness of the formed resist film was set as 30 nm. With the exception of the above, operations and evaluations were performed in the same way as in Example 1. The results are shown in Table 10.

TABLE 10

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 61 | A1 | B2 | 30 | 50 | 100 | A | B |
| Example 62 | A1 | B2 | | 45 | 100 | A | B |
| Example 63 | A1 | B2 | | 40 | 100 | A | B |
| Example 64 | A1 | B2 | | 35 | 100 | A | A |
| Example 65 | A1 | B2 | | 30 | 100 | A | A |
| Example 66 | A1 | B2 | | 25 | 100 | A | A |
| Example 67 | A1 | B2 | | 20 | 99.6 | B | A |
| Comparative | A1 | B2 | | 15 | 97.7 | C | A |
| Example 21 | | | | | | | |
| Comparative | A1 | B2 | | 10 | 95.8 | C | A |
| Example 22 | | | | | | | |
| Comparative | A1 | B2 | | 5 | 93.9 | C | A |
| Example 23 | | | | | | | |

### Examples 68 to 75 and Comparative Examples 24 and 25

B2 was used instead of B1 as a copolymer B. Moreover, the mass proportion of the copolymer B relative to total mass of the copolymer A and the copolymer B in the positive resist composition was changed to 50% (Example 68), 45% (Example 69), 40% (Example 70), 35% (Example 71), 30% (Example 72), 25% (Example 73), 20% (Example 74), 15% (Example 75), 10% (Comparative Example 24), or 5% (Comparative Example 25). Furthermore, the spinning speed was changed to 2,700 rpm, and the thickness of the formed resist film was set as 40 nm. With the exception of the above, operations and evaluations were performed in the same way as in Example 1. The results are shown in Table 11.

TABLE 11

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 68 | A1 | B2 | 40 | 50 | 100 | A | C |
| Example 69 | A1 | B2 | | 45 | 100 | A | B |
| Example 70 | A1 | B2 | | 40 | 100 | A | B |
| Example 71 | A1 | B2 | | 35 | 100 | A | B |
| Example 72 | A1 | B2 | | 30 | 100 | A | A |
| Example 73 | A1 | B2 | | 25 | 100 | A | A |
| Example 74 | A1 | B2 | | 20 | 100 | A | A |
| Example 75 | A1 | B2 | | 15 | 99.6 | B | A |
| Comparative | A1 | B2 | | 10 | 97.1 | C | A |
| Example 24 | | | | | | | |
| Comparative | A1 | B2 | | 5 | 94.6 | C | A |
| Example 25 | | | | | | | |

### Examples 76 to 83 and Comparative Examples 26 and 27

B2 was used instead of B1 as a copolymer B. Moreover, the mass proportion of the copolymer B relative to total mass of the copolymer A and the copolymer B in the positive resist composition was changed to 50% (Example 76), 45% (Example 77), 40% (Example 78), 35% (Example 79), 30% (Example 80), 25% (Example 81), 20% (Example 82), 15% (Example 83), 10% (Comparative Example 26), or 5% (Comparative Example 27). Furthermore, the spinning speed was changed to 1,900 rpm, and the thickness of the formed resist film was set as 50 nm. With the exception of the above, operations and evaluations were performed in the same way as in Example 1. The results are shown in Table 12.

TABLE 12

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 76 | A1 | B2 | 50 | 50 | 100 | A | C |
| Example 77 | A1 | B2 | | 45 | 100 | A | C |
| Example 78 | A1 | B2 | | 40 | 100 | A | C |
| Example 79 | A1 | B2 | | 35 | 100 | A | B |
| Example 80 | A1 | B2 | | 30 | 100 | A | A |
| Example 81 | A1 | B2 | | 25 | 100 | A | A |
| Example 82 | A1 | B2 | | 20 | 100 | A | A |
| Example 83 | A1 | B2 | | 15 | 100 | A | A |
| Comparative | A1 | B2 | | 10 | 98.4 | C | A |
| Example 26 | | | | | | | |
| Comparative | A1 | B2 | | 5 | 95.2 | C | A |
| Example 27 | | | | | | | |

### Examples 84 to 92 and Comparative Example 28

B2 was used instead of B1 as a copolymer B. Moreover, the mass proportion of the copolymer B relative to total mass of the copolymer A and the copolymer B in the positive resist composition was changed to 50% (Example 84), 45% (Example 85), 40% (Example 86), 35% (Example 87), 30% (Example 88), 25% (Example 89), 20% (Example 90), 15% (Example 91), 10% (Example 92), or 5% (Comparative Example 28). Furthermore, the spinning speed was changed to 1,200 rpm, and the thickness of the formed resist film was set as 60 nm. With the exception of the above, operations and evaluations were performed in the same way as in Example 1. The results are shown in Table 13.

TABLE 13

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 84 | A1 | B2 | 60 | 50 | 100 | A | C |
| Example 85 | A1 | B2 | | 45 | 100 | A | C |
| Example 86 | A1 | B2 | | 40 | 100 | A | C |
| Example 87 | A1 | B2 | | 35 | 100 | A | C |
| Example 88 | A1 | B2 | | 30 | 100 | A | B |
| Example 89 | A1 | B2 | | 25 | 100 | A | A |
| Example 90 | A1 | B2 | | 20 | 100 | A | A |
| Example 91 | A1 | B2 | | 15 | 100 | A | A |
| Example 92 | A1 | B2 | | 10 | 99.6 | B | A |
| Comparative | A1 | B2 | | 5 | 95.8 | C | A |
| Example 28 | | | | | | | |

### Examples 93 to 101 and Comparative Example 29

B2 was used instead of B1 as a copolymer B. Moreover, the mass proportion of the copolymer B relative to total mass of the copolymer A and the copolymer B in the positive resist composition was changed to 50% (Example 93), 45% (Example 94), 40% (Example 95), 35% (Example 96), 30% (Example 97), 25% (Example 98), 20% (Example 99), 15% (Example 100), 10% (Example 101), or 5% (Comparative Example 29). Furthermore, the spinning speed was changed to 700 rpm, and the thickness of the formed resist film was set as 70 nm. With the exception of the above, operations and evaluations were performed in the same way as in Example 1. The results are shown in Table 14.

TABLE 14

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 93 | A1 | B2 | 70 | 50 | 100 | A | C |
| Example 94 | A1 | B2 | | 45 | 100 | A | C |
| Example 95 | A1 | B2 | | 40 | 100 | A | C |
| Example 96 | A1 | B2 | | 35 | 100 | A | C |
| Example 97 | A1 | B2 | | 30 | 100 | A | C |
| Example 98 | A1 | B2 | | 25 | 100 | A | B |
| Example 99 | A1 | B2 | | 20 | 100 | A | A |
| Example 100 | A1 | B2 | | 15 | 100 | A | A |
| Example 101 | A1 | B2 | | 10 | 99.9 | B | A |
| Comparative | A1 | B2 | | 5 | 96.5 | C | A |
| Example 29 | | | | | | | |

### Examples 102 to 110 and Comparative Example 30

B2 was used instead of B1 as a copolymer B. Moreover, the mass proportion of the copolymer B relative to total mass of the copolymer A and the copolymer B in the positive resist composition was changed to 50% (Example 102), 45% (Example 103), 40% (Example 104), 35% (Example 105), 30% (Example 106), 25% (Example 107), 20% (Example 108), 15% (Example 109), 10% (Example 110), or 5% (Comparative Example 30). Furthermore, the spinning speed was changed to 400 rpm, and the thickness of the formed resist film was set as 80 nm. With the exception of the above, operations and evaluations were performed in the same way as in Example 1. The results are shown in Table 15.

TABLE 15

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 102 | A1 | B2 | 80 | 50 | 100 | A | C |
| Example 103 | A1 | B2 | | 45 | 100 | A | C |
| Example 104 | A1 | B2 | | 40 | 100 | A | C |
| Example 105 | A1 | B2 | | 35 | 100 | A | C |
| Example 106 | A1 | B2 | | 30 | 100 | A | C |
| Example 107 | A1 | B2 | | 25 | 100 | A | C |
| Example 108 | A1 | B2 | | 20 | 100 | A | B |
| Example 109 | A1 | B2 | | 15 | 100 | A | A |
| Example 110 | A1 | B2 | | 10 | 100 | B | A |
| Comparative | A1 | B2 | | 5 | 97.1 | C | A |
| Example 30 | | | | | | | |

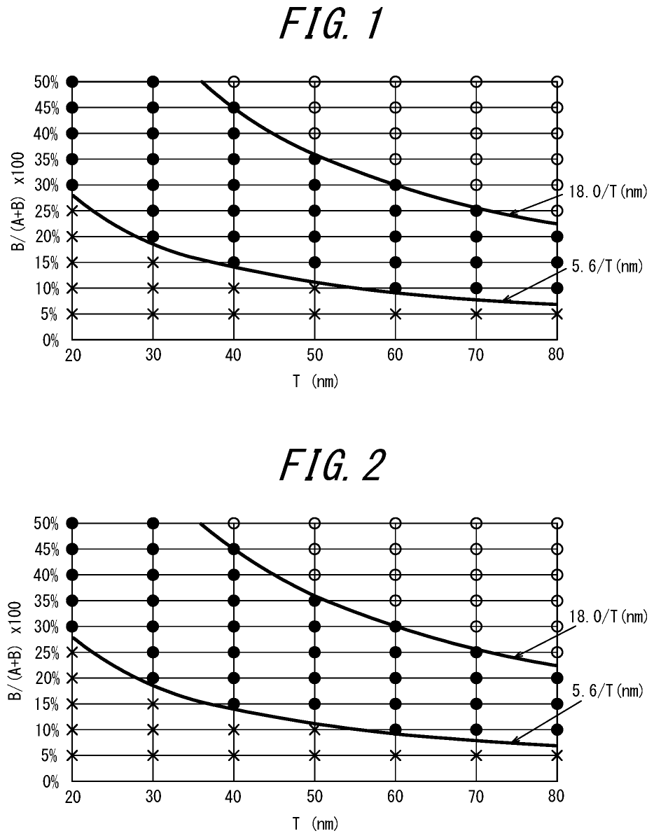

The results of Examples 56 to 110 and Comparative Examples 16 to 30 are summarized in FIG. 2. The vertical axis and horizontal axis of FIG. 2 and “white circles”, “black circles”, and “crosses” in FIG. 2 are the same as in FIG. 1.

### Examples 111 to 113 and Comparative Example 31

B3 was used instead of B1 as a copolymer B. Moreover, the mass proportion of the copolymer B relative to total mass of the copolymer A and the copolymer B in the positive resist composition was changed to 40% (Example 111), 30% (Example 112), 20% (Example 113), or 10% (Comparative Example 31). Furthermore, the spinning speed was changed to 4,200 rpm, and the thickness of the formed resist film was set as 30 nm. With the exception of the above, operations and evaluations were performed in the same way as in Example 1. The results are shown in Table 16.

TABLE 16

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 111 | A1 | B3 | 30 | 40 | 100 | A | A |
| Example 112 | A1 | B3 | | 30 | 100 | B | A |
| Example 113 | A1 | B3 | | 20 | 100 | B | A |
| Comparative | A1 | B3 | | 10 | 98.1 | C | A |
| Example 31 | | | | | | | |

### Examples 114 to 116 and Comparative Example 32

B3 was used instead of B1 as a copolymer B. Moreover, the mass proportion of the copolymer B relative to total mass of the copolymer A and the copolymer B in the positive resist composition was changed to 40% (Example 114), 30% (Example 115), 20% (Example 116), or 10% (Comparative Example 32). Furthermore, the spinning speed was changed to 1,900 rpm, and the thickness of the formed resist film was set as 50 nm. With the exception of the above, operations and evaluations were performed in the same way as in Example 1. The results are shown in Table 17.

TABLE 17

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 114 | A1 | B3 | 50 | 40 | 100 | A | C |
| Example 115 | A1 | B3 | | 30 | 100 | A | A |
| Example 116 | A1 | B3 | | 20 | 100 | B | A |
| Comparative | A1 | B3 | | 10 | 98.5 | C | A |
| Example 32 | | | | | | | |

### Examples 117 to 120

B3 was used instead of B1 as a copolymer B. Moreover, the mass proportion of the copolymer B relative to total mass of the copolymer A and the copolymer B in the positive resist composition was changed to 40% (Example 117), 30% (Example 118), 20% (Example 119), or 10% (Example 120). Furthermore, the spinning speed was changed to 700 rpm, and the thickness of the formed resist film was set as 70 nm. With the exception of the above, operations and evaluations were performed in the same way as in Example 1. The results are shown in Table 18.

TABLE 18

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 117 | A1 | B3 | 70 | 40 | 100 | A | C |
| Example 118 | A1 | B3 | | 30 | 100 | A | C |
| Example 119 | A1 | B3 | | 20 | 100 | A | A |
| Example 120 | A1 | B3 | | 10 | 100 | B | A |

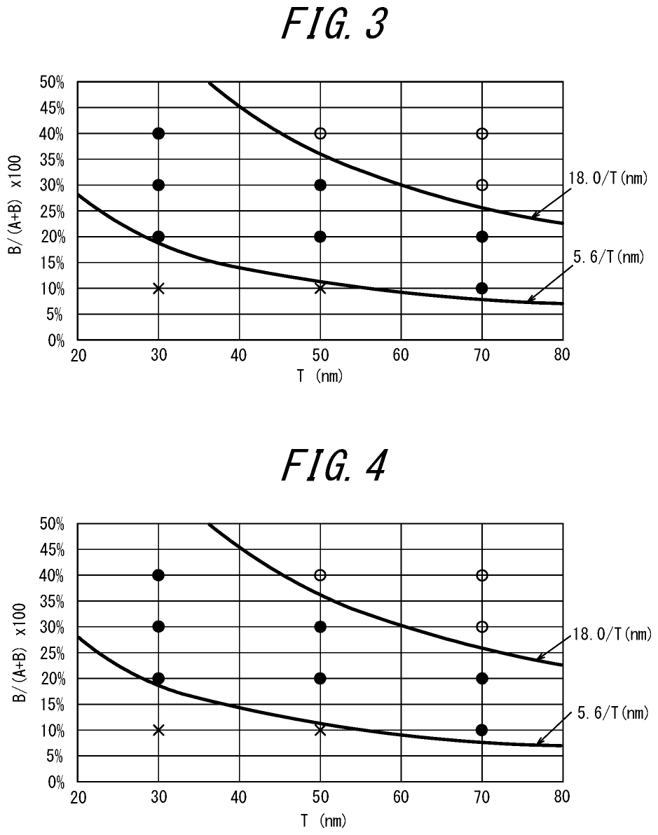

The results of Examples 111 to 120 and Comparative Examples 31 and 32 are summarized in FIG. 3. The vertical axis and horizontal axis of FIG. 3 and “white circles”, “black circles”, and “crosses” in FIG. 3 are the same as in FIG. 1.

### Examples 121 to 123 and Comparative Example 33

B4 was used instead of B1 as a copolymer B. Moreover, the mass proportion of the copolymer B relative to total mass of the copolymer A and the copolymer B in the positive resist composition was changed to 40% (Example 121), 30% (Example 122), 20% (Example 123), or 10% (Comparative Example 33). Furthermore, the spinning speed was changed to 4,200 rpm, and the thickness of the formed resist film was set as 30 nm. With the exception of the above, operations and evaluations were performed in the same way as in Example 1. The results are shown in Table 19.

TABLE 19

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 121 | A1 | B4 | 30 | 40 | 100 | A | B |
| Example 122 | A1 | B4 | | 30 | 100 | A | A |
| Example 123 | A1 | B4 | | 20 | 99.1 | B | A |
| Comparative | A1 | B4 | | 10 | 92.5 | C | A |
| Example 33 | | | | | | | |

### Examples 124 to 126 and Comparative Example 34

B4 was used instead of B1 as a copolymer B. Moreover, the mass proportion of the copolymer B relative to total mass of the copolymer A and the copolymer B in the positive resist composition was changed to 40% (Example 124), 30% (Example 125), 20% (Example 126), or 10% (Comparative Example 34). Furthermore, the spinning speed was changed to 1,900 rpm, and the thickness of the formed resist film was set as 50 nm. With the exception of the above, operations and evaluations were performed in the same way as in Example 1. The results are shown in Table 20.

TABLE 20

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 124 | A1 | B4 | 50 | 40 | 100 | A | C |
| Example 125 | A1 | B4 | | 30 | 100 | A | B |
| Example 126 | A1 | B4 | | 20 | 100 | A | A |
| Comparative | A1 | B4 | | 10 | 96.7 | C | A |
| Example 34 | | | | | | | |

### Examples 127 to 130

B4 was used instead of B1 as a copolymer B. Moreover, the mass proportion of the copolymer B relative to total mass of the copolymer A and the copolymer B in the positive resist composition was changed to 40% (Example 127), 30% (Example 128), 20% (Example 129), or 10% (Example 130). Furthermore, the spinning speed was changed to 700 rpm, and the thickness of the formed resist film was set as 70 nm. With the exception of the above, operations and evaluations were performed in the same way as in Example 1. The results are shown in Table 21.

TABLE 21

| | Positive resist composition | | Film | | | Remaining | |
|---|---|---|---|---|---|---|---|
| | Copolymer | Copolymer | thickness | B/(A + B) × | Ratio of | film | Remaining |
| | A | B | [nm] | 100 [%] | coverage | fraction | residues |
| Example 127 | A1 | B4 | 70 | 40 | 100 | A | C |
| Example 128 | A1 | B4 | | 30 | 100 | A | C |
| Example 129 | A1 | B4 | | 20 | 100 | A | B |
| Example 130 | A1 | B4 | | 10 | 100 | A | A |

The results of Examples 123 to 130 and Comparative Examples 33 and 34 are summarized in FIG. 4. The vertical axis and horizontal axis of FIG. 4 and “white circles”, “black circles”, and “crosses” in FIG. 4 are the same as in FIG. 1.

It can be seen from the results illustrated in Tables 2 to 21 and FIGS. 1 to 4 that it is possible to form a resist pattern having little resist pattern top loss in Examples 1 to 130 (“white circles” and “black circles” in FIGS. 1 to 4) in which the mass proportion of the copolymer B relative to total mass of the copolymer A and the copolymer B in the positive resist composition and the thickness of the resist film formed by applying the positive resist composition onto the substrate satisfy a specific relationship.

### INDUSTRIAL APPLICABILITY

By using the presently disclosed positive resist composition, it is possible to form a resist pattern having little resist pattern top loss.

1. A positive resist composition comprising: a copolymer A that is of a main chain scission-type and that includes a fluorine substituent; a copolymer B that is of a main chain scission-type and that includes a fluorine substituent; and a solvent, wherein
a difference between surface free energy of the copolymer A and surface free energy of the copolymer B is 4 mJ/m² or more, and
a mass proportion of the copolymer B relative to total mass of the copolymer A and the copolymer B in the positive resist composition and thickness of a positive resist film formed by applying the positive resist composition onto a substrate satisfy a relationship expressed by formula (1), shown below,
$$B / ( A + B ) \times 100 ( \% ) \geq 5.6 / T \times 100 ( \% ) \qquad ( 1 )$$
where, in formula (1), A represents mass of the copolymer A in the positive resist composition, B represents mass of the copolymer B in the positive resist composition, and T represents thickness, in units of nanometers, of the positive resist film.

2. The positive resist composition according to claim 1, not substantially comprising a component having a weight-average molecular weight (Mw) of less than 1,000.

3. The positive resist composition according to claim 1, further satisfying a relationship expressed by formula (2), shown below,
$$18. / T \times 100 ( \% ) \geq B / ( A + B ) \times 100 ( \% ) \qquad ( 2 )$$
where, in formula (2), A represents mass of the copolymer A in the positive resist composition, B represents mass of the copolymer B in the positive resist composition, and T represents thickness, in units of nanometers, of the positive resist film.

4. The positive resist composition according to claim 1, wherein the copolymer A includes:
a monomer unit (I) represented by formula (I), shown below, 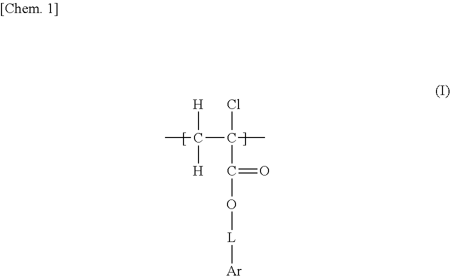
where, in formula (I), L is a divalent linking group that includes a fluorine atom, and Ar is an optionally substituted aromatic ring group; and
a monomer unit (II) represented by formula (II), shown below, 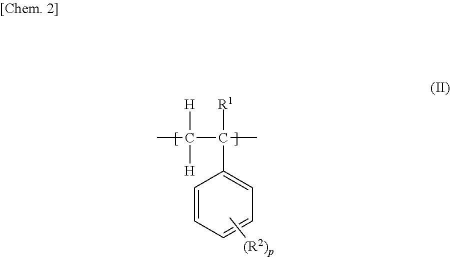
where, in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different.

5. The positive resist composition according to claim 1, wherein the copolymer B includes:
a monomer unit (III) represented by formula (III), shown below, 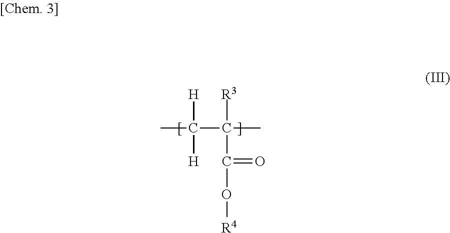
where, in formula (III), R³ is a hydrogen atom, an alkyl group, a halogen atom, a haloalkyl group, a cyano group, an alkoxy group, an acyl group, or an alkyl ester group, and R⁴ is an organic group including 5 or 7 fluorine atoms; and
a monomer unit (II) represented by formula (II), shown below, 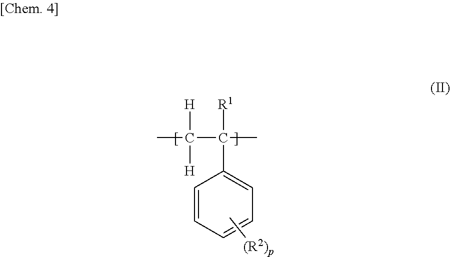
where, in formula (II), R¹ is an alkyl group, R² is a hydrogen atom, an alkyl group, a halogen atom, a haloalkyl group, a hydroxy group, or a carboxy group, p is an integer of not less than 0 and not more than 5, and in a case in which more than one R² is present, each R² may be the same or different.
